(19) United States
(12) Patent Application Publication
(10) Pub. No.: US 2026/0123214 A1
(43) Pub. Date: Apr. 30, 2026

(54) Display Panel and Display Device Including the Same

(71) Applicant: LG Display Co., Ltd., Seoul (KR)

(72) Inventors: Inyeong Kong, Seoul (KR); Seunghwan Shin, Jeonju-si (KR); Wonho Lee, Paju-si (KR); Youngmin Jeong, Paju-si (KR)

(21) Appl. No.: 19/319,116

(22) Filed: Sep. 4, 2025

(30) Foreign Application Priority Data
Oct. 25, 2024 (KR) 10-2024-0147267

(51) Int. Cl. H10K 59/131; G09G 3/3233

(52) U.S. Cl. CPC H10K 59/131; G09G 3/3233; G09G 2300/0426; G09G 2300/0452; G09G 2300/0842; G09G 2310/08; G09G 2320/0233; G09G 2320/0295; G09G 2320/045

(57) ABSTRACT

Disclosed is a display panel in which a high potential voltage line is further disposed between pixels adjacent to each other in a row direction so that driving circuits of the adjacent pixels are arranged so as to be asymmetrical with each other around the high potential voltage line. To this end, a position of the driving circuit for at least one sub-pixel among the plurality of sub-pixels in one pixel is opposite, in a column direction, to a position of the driving circuit for corresponding at least one sub-pixel among the plurality of sub-pixels of another pixel adjacent to one pixel in the row direction. Thus, a column line defect due to a deviation between the parasitic capacitances of sub-pixels of an odd-numbered row and an even-numbered row emitting light of the same color according to a process variation is suppressed.

### CROSS-REFERENCE TO RELATED APPLICATION

This application claims priority from Republic of Korea Patent Application No. 10-2024-0147267 filed on Oct. 25, 2024, which is hereby incorporated by reference in its entirety.

### BACKGROUND

### Field

The present disclosure relates to a display device, and more particularly, to a display panel in which a high potential voltage line is additionally disposed between adjacent ones of a plurality of pixels, and a display device including the same.

### Description of Related Art

Display devices used in a computer monitor, a television (TV), a mobile phone, or the like include an organic light-emitting display device (OLED) that emits light by itself, and a liquid crystal display device (LCD) that requires a separate light source.

Among these various display devices, the organic light-emitting display device includes a display panel including a plurality of pixels and a driver for driving the display panel. The driver includes a gate driver for supplying a gate signal to the display panel and a data driver for supplying a data voltage. When a signal such as a gate signal and a data voltage is supplied to a sub-pixel included in each of the pixels of the organic light-emitting display device, the selected sub-pixel may emit light to display an image.

### SUMMARY

In a conventional display device, in a single rate driving (SRD) scheme based on the three sub-pixels, one high potential voltage line is used to drive the six sub-pixels. Thus, when the DRD based on the three sub-pixels is designed in the same arrangement as in the SRD scheme, a column line defect may occur due to the left-right asymmetry.

Accordingly, there is a need for a display device in which the column line defect between an odd-numbered column and the even-numbered column in the pixel arrangement based on the SRD scheme is suppressed.

Accordingly, the inventors of the present disclosure have invented a display panel in which a high potential voltage line is additionally disposed between adjacent ones of a plurality of pixels in the pixel arrangement based on the SRD scheme, thereby suppressing the column line defect between an odd-numbered column and an even-numbered column due to a process variation.

A technical purpose of the present disclosure is to provide a display panel in which a high potential voltage line is additionally disposed between adjacent ones of a plurality of pixels in the pixel arrangement based on the SRD scheme, thereby suppressing the column line defect due to a process variation.

In addition, a technical purpose of the present disclosure is to provide a display panel in which a high potential voltage line is further disposed between adjacent ones of a plurality of pixels so that driving circuits of the pixels adjacent to each other in the row direction are arranged so as to be asymmetrical with each other around the high potential voltage line, thereby suppressing the column line defect occurring between the odd-numbered column and the even-numbered column during the process due to the left-right asymmetry.

In addition, a technical purpose of the present disclosure is to provide a display panel in which when the same line structure as that in the SRD scheme is applied to the DRD structure based on three sub-pixels, lines respectively adjacent to sub-pixels emitting light of the same color are positioned in different manners.

In addition, a technical purpose of the present disclosure is to provide a display panel in which a first high potential voltage line is disposed on one side in a row direction of a first pixel, a second high potential voltage line is disposed on the other side in the row direction of a second pixel disposed at a position adjacent to the first pixel in the row direction, and a third high potential voltage line is disposed between the first pixel and the second pixel.

In addition, a technical purpose of the present disclosure is to provide a display device in which each driving circuit is configured to drive each of a plurality of sub-pixels of each of first and second pixels, wherein each driving circuit is disposed on one or the other of both opposing sides in a column direction of each corresponding sub-pixel such that at least one of the driving circuits corresponding to the sub-pixels of the first pixel and at least one of the driving circuits corresponding to the sub-pixels of the second pixel are arranged in the row direction in a staggered manner.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In one embodiment, a display panel comprises: a first pixel including a plurality of first sub-pixels; a second pixel including a plurality of second sub-pixels, the second pixel adjacent to the first pixel in a first direction; a first high potential voltage line on a first side of the first pixel in the first direction; a second high potential voltage line on a second side of the second pixel in the first direction; and a third high potential voltage line between the first pixel and the second pixel such that the third high potential voltage line is on a second side of the first pixel and a first side of the second pixel.

In one embodiment, a display panel comprises: a pixel row including a first pixel comprising a plurality of first sub-pixels and a second pixel comprising a plurality of second sub-pixels, the second pixel adjacent to the first pixel in the pixel row along a first direction; a first high potential voltage line on a first side of the first pixel in a plan view of the display panel, the first high potential voltage line connected to at least one of the plurality of first sub-pixels of the first pixel; a second high potential voltage line on a second side of the second pixel in the plan view of the display panel, the second high potential voltage line connected to at least one of the plurality of second sub-pixels of the second pixel; and a third high potential voltage line between the first pixel and the second pixel, the third high potential voltage line connected to at least another one of the plurality of first sub-pixels of the first pixel and at least another one of the plurality of second sub-pixels of the second pixel.

A display device according to an embodiment of the present disclosure includes a display panel in which a high potential voltage line is additionally disposed between adjacent ones of a plurality of pixels so that driving circuits of the pixels adjacent to each other in the row direction are arranged so as to be asymmetrical with each other around the high potential voltage line.

According to an embodiment of the present disclosure, the high potential voltage line is additionally disposed between adjacent ones of the plurality of pixels such that driving circuits of first and second pixels adjacent to each other in the row direction are arranged so as to be asymmetrical with each other around the high potential voltage line, thereby suppressing the column line defect between the odd-numbered column and the even-numbered column due to the deviation in the parasitic capacitance.

In addition, according to another embodiment of the present disclosure, the position of the driving circuit for at least one sub-pixel among the plurality of sub-pixels in one pixel is opposite, in the column direction, to the position of the driving circuit for corresponding at least one sub-pixel among the plurality of sub-pixels of another pixel adjacent to one pixel in the row direction that the driving circuits of the pixels adjacent to each other in the row direction are arranged so as to be asymmetrical with each other in the row direction.

In addition, according to another embodiment of the present disclosure, the high potential voltage line is additionally disposed between the first and second pixels so that the position of the driving circuit for at least one sub-pixel among the plurality of sub-pixels in the first pixel is opposite, in the column direction, to the position of the driving circuit for corresponding at least one sub-pixel among the plurality of sub-pixels of the second pixel adjacent to one pixel in the row direction that the driving circuits of the first and second pixels adjacent to each other in the row direction are arranged so as to be asymmetrical with each other around the high potential voltage line, suppressing the column line defect due to the deviation between the parasitic capacitances of sub-pixels of the odd-numbered column and the even-numbered column emitting light of the same color according to the process variation.

In addition, according to another embodiment of the present disclosure, when the DRD based on the three sub-pixels is designed in the same arrangement as in the SRD scheme, the occurrence of the column line defect between the odd-numbered column and the even-numbered column due to the process variation may be suppressed.

In addition, according to another embodiment of the present disclosure, in the DRD structure, each driving circuit is disposed on one or the other of both opposing sides in a column direction of each corresponding sub-pixel such that at least one of the driving circuits corresponding to the sub-pixels of the first pixel and at least one of the driving circuits corresponding to the sub-pixels of the second pixel are arranged in the row direction in a staggered manner. Thus, a difference between an arrangement of the storage capacitor and the gate line and the arrangement between another storage capacitor and the gate line due to the overlay variation is greatly reduced. Thus, the column line defect is suppressed.

In addition, according to another embodiment of the present disclosure, the high potential voltage line is additionally disposed between adjacent ones of the plurality of pixels such that driving circuits of first and second pixels adjacent to each other in the row direction are arranged so as to be asymmetrical with each other around the high potential voltage line, thereby suppressing the column line defect due to the process variation to achieve the process optimization, and thus reducing production energy due to the process optimization.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

FIG. 1 is a schematic diagram of a display device according to an embodiment of the present disclosure.

FIG. 2 is a circuit diagram of a sub-pixel of a display device according to an embodiment of the present disclosure.

FIG. 3 is an example diagram illustrating an arrangement relationship of sub-pixels of a display device according to an embodiment of the present disclosure.

FIG. 4 is a timing diagram of a gate voltage and a data voltage when a display device displays a monochromatic still screen according to an embodiment of the present disclosure.

FIG. 5 is a timing diagram of a gate voltage and a data voltage when a display device displays a vertical pattern screen according to an embodiment of the present disclosure.

FIG. 6 is an example diagram illustrating a pixel arrangement when a display device according to an embodiment of the present disclosure operates in a single rate driving (SRD) driving manner.

FIG. 7 is a first example diagram in which a high potential voltage line is additionally disposed between adjacent ones of a plurality of pixels according to an embodiment of the present disclosure.

FIG. 8 is a second example diagram in which a high potential voltage line is additionally disposed between adjacent ones of a plurality of pixels according to an embodiment of the present disclosure.

FIG. 9 is a third example diagram in which a high potential voltage line is additionally disposed between adjacent ones of a plurality of pixels according to an embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally. In a plan view of the display device, a column direction and a row direction intersecting each other are used to define an extension direction of a component, for example, a line.

Hereinafter, various embodiments of the present disclosure will be described in detail with reference to the accompanying drawings.

A transistor used in the display device of the present disclosure may be embodied as one or more transistors of an n-channel transistor NMOS and a p-channel transistor PMOS. The transistor may be embodied as an oxide semiconductor transistor having an oxide semiconductor layer as an active layer or an LTPS transistor having a low temperature poly-silicon (LTPS) layer as an active layer. The transistor may include at least a gate electrode, a source electrode, and a drain electrode. The transistor may be embodied as a thin-film transistor (TFT) on the display panel. The carriers in the transistor flows from the source electrode to the drain electrode. In the n-channel transistor NMOS, since the carriers are electrons, the source voltage is lower than the drain voltage so that electrons may flow from the source electrode to the drain electrode. In the n-channel transistor NMOS, the current flows from the drain electrode to the source electrode, and the source electrode may be an output terminal. In the p-channel transistor PMOS, since the carrier is a hole, the source voltage is higher than the drain voltage so that the hole may flow from the source electrode to the drain electrode. In the p-channel transistor PMOS, since holes flow from the source electrode to the drain electrode, a current flows from the source electrode to the drain electrode, and the drain electrode may be an output terminal. Therefore, it should be noted that the source and the drain of the transistor are not fixed because the source and the drain may be exchanged with each other based on the applied voltage. In the present disclosure, it is assumed that the transistor is an n-channel transistor (NMOS). However, embodiments of the present disclosure are not limited thereto, and the transistor may be embodied as an p-channel transistor, and accordingly, a circuit configuration may be changed.

A gate signal of a transistor used as each of switch elements swings between a gate-on voltage and a gate-off voltage. The gate-on voltage is set to a voltage higher than the threshold voltage Vth of the transistor, and the gate-off voltage is set to a voltage lower than the threshold voltage Vth of the transistor. The transistor is turned on in response to the gate-on voltage VGL, while being turned off in response to the gate-off voltage VGL. In the NMOS, the gate-on voltage may be the gate high voltage VGH, and the gate-off voltage may be the gate low voltage VGL. In the PMOS, the gate-on voltage may be the gate low voltage VGL, and the gate-off voltage may be the gate high voltage VGH.

Hereinafter, various embodiments of the present disclosure will be described in detail with reference to the accompanying drawings.

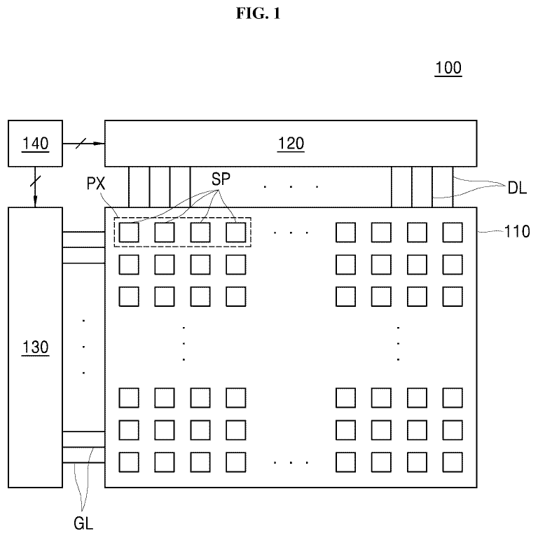

FIG. 1 is a schematic diagram of a display device according to an embodiment of the present disclosure.

Referring to FIG. 1, a display device 100 according to an embodiment of the present disclosure may include a display panel 110, a gate driver 120, a data driver 130, and a timing controller 140.

The configuration of the display panel 110 illustrated in FIG. 1 is merely according to an embodiment, and the components of the display panel 110 are not limited to those in the embodiment as illustrated in FIG. 1, and some components may be added, changed, or deleted as necessary.

According to an embodiment, the display panel 110 is a panel for displaying an image. The display panel 110 may include various circuits, lines, and light-emitting elements disposed on a substrate. An area of the display panel 110 may divide into pixels areas defined by a plurality of data lines DL and a plurality of gate lines GL intersecting each other, and may include a plurality of pixels PX respectively disposed in the pixel areas and connected to the plurality of data lines DL and the plurality of gate lines GL.

The display panel 110 may include a display area including the plurality of pixels PX and a non-display area in which various signal lines or pads are formed.

The display panel 110 may be embodied as a display panel 110 used in various display devices such as a liquid crystal display device, an organic light-emitting display device, an electrophoretic display device, etc.

Hereinafter, an example is described in which the display panel 110 is a panel used in an organic light-emitting display device. However, embodiments of the present disclosure are not limited thereto.

According to an embodiment, the timing controller 140 may receive a timing signal such as a vertical synchronization signal, a horizontal synchronization signal, a data enable signal, and a dot clock via a receiving circuit such as an LVDS or TMDS interface connected to a host system. The timing controller 140 may generate timing control signals for controlling the gate driver 120 and the data driver 130 based on the input timing signal.

According to an embodiment, the gate driver 120 may supply a data voltage DATA to the plurality of sub-pixels SP. The gate driver 120 may include a plurality of source drive integrated circuits (IC). The plurality of source drive IC may receive digital video data and a source timing control signal from the timing controller 140.

The plurality of source drive ICs may convert the digital video data into a gamma voltage in response to the source timing control signal to generate the data voltage DATA, and may supply the data voltage DATA via the data line DL of the display panel 110. The plurality of source drive ICs may be connected to the data line DL of the display panel 110 in a chip on glass (COG) process or a tape automated bonding (TAB) process.

In addition, the source drive ICs may be formed on the display panel 110 or may be formed on a separate PCB substrate which may be connected to the display panel 110.

According to an embodiment, the data driver 130 may supply a gate signal to the plurality of sub-pixels SP. The data driver 130 may include a level shifter and a shift register. The level shifter may shift a level of a clock signal input from the timing controller 140 to a transistor-transistor-logic (TTL) level and then supply the signal having the shifted level to the shift register. The shift register may be formed in the non-display area of the display panel 110 in an GIP (gate in panel) manner. However, embodiments of the present disclosure are not limited thereto.

The shift register may include a plurality of stages that shift and output the gate signal in response to the clock signal and a driving signal. The plurality of stages included in the shift register may sequentially output the gate signal via a plurality of output terminals.

According to an embodiment, the display panel 110 may include a plurality of sub-pixels SP. The plurality of sub-pixels SP may be sub-pixels SP for emitting light of different colors. For example, the plurality of sub-pixels SP may include a red sub-pixel, a green sub-pixel, a blue sub-pixel, and a white sub-pixel. However, embodiments of the present disclosure are not limited thereto. The plurality of sub-pixels SP may constitute the pixel PX.

That is, the red sub pixel, the green sub pixel, the blue sub pixel, and the white sub pixel may constitute a single pixel PX, and the display panel 110 may include a plurality of pixels PX.

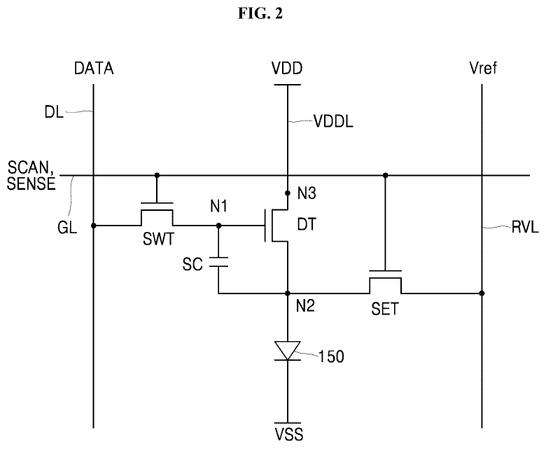

Hereinafter, for a more detailed description of a driving circuit for driving one sub-pixel SP, FIG. 2 will be referred to together with FIG. 1.

FIG. 2 is a circuit diagram of a sub-pixel of a display device according to an embodiment of the present disclosure.

FIG. 2 illustrates a circuit diagram of one sub-pixel SP among the plurality of sub-pixels SP of the display device 100.

Referring to FIG. 2, the sub-pixel SP may include a switching transistor SWT, a sensing transistor SET, a driving transistor DT, a storage capacitor SC, and a light-emitting element 150.

According to an embodiment, the light-emitting element 150 may include an anode, an organic layer stack, and a cathode. The organic layer stack may include a stack of various organic layers such as a hole injection layer, a hole transport layer, an organic light-emitting layer, an electron transport layer, and an electron injection layer. The anode of the light-emitting element 150 may be connected to an output terminal of the driving transistor DT, and a low potential voltage VSS may be applied to the cathode of the light-emitting element 150.

Although FIG. 2 illustrates that the light-emitting element 150 is embodied as the organic light-emitting element 150, the present disclosure is not limited thereto, and an inorganic light-emitting diode, that is, LED, may also be used as the light-emitting element 150.

Referring to FIG. 2, the switching transistor SWT is a transistor for transferring the data voltage DATA to a first node N1 connected to a gate electrode of the driving transistor DT. The switching transistor SWT may include a drain electrode connected to the data line DL, a gate electrode connected to the gate line GL, and a source electrode connected to the gate electrode of the driving transistor DT. The switching transistor SWT may be turned on based on a gate voltage GATE applied from the gate line GL to transmit the data voltage DATA supplied from the data line DL to the first node N1 connected to the gate electrode of the driving transistor DT.

Referring to FIG. 2, the driving transistor DT is a transistor for driving the light-emitting element 150 by supplying a driving current to the light-emitting element 150. The driving transistor DT may include a gate electrode connected to the first node N1, a source electrode connected to a second node N2 and corresponding to an output terminal, and a drain electrode connected to a third node N3 and corresponding to an input terminal.

The gate electrode of the driving transistor DT may be connected to the switching transistor SWT, a drain electrode thereof may receive a high potential voltage VDD via a high potential voltage line VDDL, and a source electrode thereof may be connected to the anode of the light-emitting element 150.

Referring to FIG. 2, the storage capacitor SC is a capacitor for maintaining a voltage corresponding to the data voltage DATA for one frame. One electrode of the storage capacitor SC may be connected to the first node N1, and the other electrode thereof may be connected to the second node N2.

In one example, in the display device 100, as an operation time of each sub-pixel SP increases, degradation of a circuit element such as the driving transistor DT may proceed. Accordingly, an intrinsic characteristic value of the circuit element such as the driving transistor DT may be changed.

In this regard, the intrinsic characteristic value of the circuit element may include the threshold voltage Vth of the driving transistor DT, the mobility α of the driving transistor DT, etc. The change in the intrinsic characteristic value of the circuit element may cause a change in luminance of the corresponding sub-pixel SP.

Therefore, the change in the intrinsic characteristic value of the circuit element may be used as the same concept as the change in the luminance of the sub-pixel SP.

In addition, the change amount in the intrinsic characteristic value of the circuit element of each sub-pixel SP may vary depending on the deterioration amount of each circuit element. Thus, the change amounts in the intrinsic characteristic value of the circuit elements of different sub-pixels SP having the different deterioration amounts of the circuit elements thereof may be different from each other. Such a difference between the change amounts in the intrinsic characteristic value of the respective circuit elements of the sub-pixels may cause a luminance deviation between luminance of the sub-pixels SP.

Therefore, the deviation between the intrinsic characteristic value of the circuit elements of the different sub-pixels SP may be used as the same concept as the luminance deviation between the luminance of the different sub-pixels SP.

The change in the intrinsic characteristic value of the circuit element, that is, the change in the luminance of the sub-pixel SP and the deviations between in the intrinsic characteristic values of the circuit elements of the sub-pixels, that is, the deviation between the luminance of the sub-pixels SP, may cause problems such as a decrease in accuracy of the luminance realized in the sub-pixel SP or a screen abnormality.

Accordingly, in the sub-pixel SP of the display device 100 according to an embodiment of the present disclosure, a sensing function of sensing the intrinsic characteristic value of the sub-pixel SP and a compensation function of compensating for the intrinsic characteristic value of the sub-pixel SP based on the sensing result may be provided.

Accordingly, as shown in FIG. 2, the sub-pixel SP may further include a sensing transistor SET for effectively controlling the voltage state of the source electrode of the driving transistor DT in addition to the switching transistor SWT, the driving transistor DT, the storage capacitor SC, and the light-emitting element 150.

Referring to FIG. 2, the sensing transistor SET is connected to and disposed between the source electrode of the driving transistor DT and a reference voltage line RVL that supplies a reference voltage Vref. A gate electrode of the sensing transistor SET is connected to the gate line GL. Accordingly, the sensing transistor SET may be turned on based on the sensing signal SENSE applied via the gate line GL to apply the reference voltage Vref supplied via the reference voltage line RVL to the source electrode of the driving transistor DT. In addition, the sensing transistor SET may be used as one of voltage sensing paths for the source electrode of the driving transistor DT.

Referring to FIG. 2, the switching transistor SWT and the sensing transistor SET of the sub-pixel SP may share one gate line GL. That is, the switching transistor SWT and the sensing transistor SET may be connected to the same gate line GL and may receive the same gate signal therefrom. However, for convenience of description, a voltage applied to the gate electrode of the switching transistor SWT is referred to as the gate voltage GATE, and a voltage applied to the gate electrode of the sensing transistor SET is referred to as a sensing signal SENSE. However, the gate voltage GATE and the sensing signal SENSE applied to one sub-pixel SP are the same signal transmitted via the same gate line GL.

However, the present disclosure is not limited thereto, and the switching transistor SWT may be connected to the gate line GL, and the sensing transistor SET may be connected to a separate sensing line. Accordingly, the gate voltage GATE may be applied to the switching transistor SWT via the gate line GL, and the sensing signal SENSE may be applied to the sensing transistor SET via the sensing line.

Accordingly, the reference voltage Vref is applied to the source electrode of the driving transistor DT via the sensing transistor SET. In addition, a voltage for sensing the threshold voltage Vth of the driving transistor DT or the mobility α of the driving transistor DT is detected via the reference voltage line RVL. In addition, the gate driver 120 may compensate for the data voltage DATA based on an amount of change in the detected threshold voltage Vth of the driving transistor DT or the detected mobility α of the driving transistor DT.

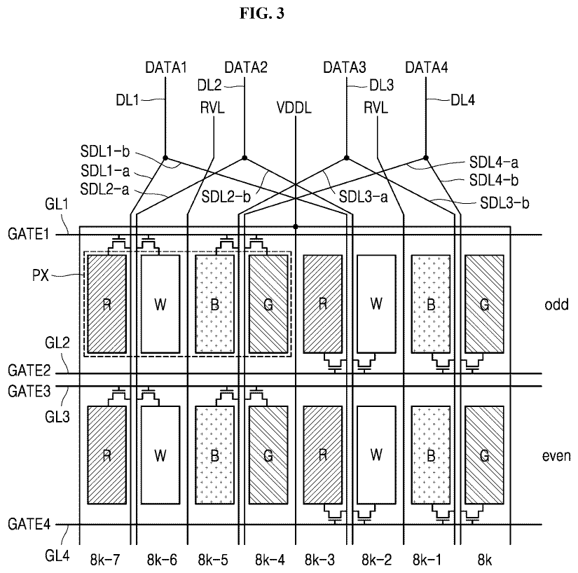

Hereinafter, FIG. 3 is further referred to describe an arrangement relationship of a plurality of sub-pixels.

FIG. 3 is an example diagram illustrating an arrangement relationship of sub-pixels of a display device according to an embodiment of the present disclosure.

For convenience of description, four pixels PX arranged in a 2×2 matrix form are illustrated in FIG. 3. An arrangement relationship of four pixels PX arranged in a 2×2 matrix form may be repeated in the display area DA. In addition, a transistor disposed between the sub-pixels R, G, B, and W and the data line means the switching transistor SWT described in FIG. 2.

According to an embodiment, each of the plurality of data lines DL1, DL2, DL3, and DL4 may divide into a plurality of sub-data lines SDL1-a and SDL1-b, SDL2-a and SDL2-b, SDL3-aand SDL3-b, or SDL4-a and SDL4-b.

Specifically, the first data line DL1 may divide into a plurality of first sub-data lines SDL1-a and SDL1-b and the second data line DL2 may divide into a plurality of second sub-data lines SDL2-a and SDL2-b.

The third data line DL3 may divide into a plurality of third sub-data lines SDL3-a and SDL3-b and the fourth data line DL4 may divide into a plurality of fourth sub-data lines SDL4-aand SDL4-b.

According to an embodiment, the first sub-data lines SDL1-a and SDL1-b may include a (1-a)th sub-data line SDL1-a and a (1-b)th sub-data line SDL1-b, and the second sub-data lines SDL2-a and SDL2-b may include a (2-a)th sub-data line SDL2-a and a (2-b)th sub-data line SDL2-b.

The third sub-data lines SDL3-a and SDL3-b may include a (3-a)th sub-data line SDL3-a and a (3-b)th sub-data line SDL3-b, and the fourth sub-data lines SDL4-a and SDL4-b may include a (4-a)th sub-data line SDL4-a and a (4-b)th sub-data line SDL4-b.

Each of the plurality of high potential voltage lines VDDL may be disposed between adjacent ones of the plurality of pixels PX.

According to an embodiment, one pixel PX may include four sub-pixels R, G, B, and W. For example, as shown in FIG. 3, the pixel PX may include a first sub-pixel R, a second sub-pixel W, a third sub-pixel B, and a fourth sub-pixel G. For example, the first sub-pixel R may be a red sub-pixel, the second sub-pixel W may be a white sub-pixel, the third sub-pixel B may be a blue sub-pixel, and the fourth sub-pixel G may be a green sub-pixel. However, the present disclosure is not limited thereto, and the plurality of sub-pixels may include sub-pixels emitting light of various colors magenta, yellow, and cyan.

In addition, the plurality of sub-pixels emitting light of the same color may be arranged in the same column. That is, the plurality of first sub-pixels R may be arranged in the same column, the plurality of second sub-pixels W may be arranged in the same column, the plurality of third sub-pixels B may be arranged in the same column, and the plurality of fourth sub-pixels G may be arranged in the same column.

More specifically, as illustrated in FIG. 3, the plurality of first sub-pixels R may be arranged in a (8k-7)th column and a (8k-3)th column, and the plurality of second sub-pixels W may be arranged in a (8k-6)th column and a (8k-2)th column. In addition, the plurality of third sub-pixels B may be arranged in a (8k-5)th column and a (8k-1)th column, and the plurality of fourth sub-pixels G may be arranged in a (8k-4)th column and a 8k-th column. However, k means a natural number greater than or equal to 1.

That is, the first sub-pixel R, the second sub-pixel W, the third sub-pixel B, and the fourth sub-pixel G may be sequentially and repeatedly arranged along one odd row or one even row even.

According to an embodiment, each of the plurality of first sub-data lines SDL1-a and SDL1-b may be disposed adjacent to the plurality of first sub-pixels R and be respectively connected to the plurality of first sub-pixels R.

Specifically, the (1-a)th sub-data line SDL1-a may be disposed between the plurality of first sub-pixels R arranged in a (8k-7)th column and the plurality of second sub-pixels W arranged in a (8k-6)th column, and may be electrically connected to the plurality of first sub-pixels R arranged in the (8k-7)th column. In addition, the (1-b)th sub-data line SDL1-b may be disposed between the plurality of first sub-pixels R arranged in a (8k-3)th column and the plurality of second sub-pixels W arranged in a (8k-2)th column, and may be electrically connected to the plurality of first sub-pixels R arranged in the (8k-3)th column.

According to an embodiment, each of the plurality of second sub-data lines SDL2-a and SDL2-b may be disposed adjacent to the plurality of second sub-pixels W and may be connected to the plurality of second sub-pixels W.

Specifically, the (2-a)th sub-data line SDL2-a may be disposed between the plurality of first sub-pixels R arranged in a (8k-7)th column and the plurality of second sub-pixels W arranged in a (8k-6)th column, and may be electrically connected to the plurality of second sub-pixels W arranged in the (8k-6)th column. In addition, the (2-b)th sub-data line SDL2-b may be disposed between the plurality of first sub-pixels R arranged in a (8k-3)th column and the plurality of second sub-pixels W arranged in a (8k-2)th column and be electrically connected to the plurality of second sub-pixels W arranged in the (8k-2)th column.

According to an embodiment, each of the plurality of third sub-data lines SDL3-a and SDL3-b may be disposed adjacent to the plurality of third sub-pixels B and may be connected to the plurality of third sub-pixels B.

Specifically, the (3-a)th sub-data line SDL3-a may be disposed between the plurality of third sub-pixels B arranged in a (8k-5)th column and the plurality of fourth sub-pixels G arranged in a (8k-4)th column, and may be electrically connected to the plurality of third sub-pixels B arranged in the (8k-5)th column. In addition, the (3-b)th sub-data line SDL3-b may be disposed between the plurality of third sub-pixels B arranged in a (8k-1)th column and the plurality of fourth sub-pixels G arranged in a 8k-th column, and may be electrically connected to the plurality of third sub-pixels B arranged in the (8k-1)th column.

According to an embodiment, each of the plurality of fourth sub-data lines SDL4-a and SDL4-W may be disposed adjacent to the plurality of fourth sub-pixels G and may be connected to the plurality of fourth sub-pixels G.

Specifically, the (4-a)th sub-data line SDL4-a may be disposed between the plurality of third sub-pixels B arranged in a (8k-5)th column and the plurality of fourth sub-pixels G arranged in a (8k-4)th column, and may be electrically connected to the plurality of fourth sub-pixels G arranged in the (8k-4)th column. The (4-b)th sub-data lines SDL4-b may be disposed between the plurality of third sub-pixels B arranged in a (8k-1)th column and the plurality of fourth sub-pixels G arranged in a 8k-th column, and may be electrically connected to the plurality of fourth sub-pixels G arranged in the 8k-th column.

According to an embodiment, a first data voltage DATA1 as a red data voltage may be applied to the first data line DL1, and a second data voltage DATA2 as a white data voltage may be applied to the second data line DL2. In addition, a third data voltage DATA3 as a blue data voltage may be applied to the third data line DL3, and a fourth data voltage DATA4 as a green data voltage may be applied to the fourth data line DL4.

Accordingly, the first data voltage DATA1 as a red data voltage may also be applied to the plurality of first sub-data lines SDL1-a and SDL1-b, and the second data voltage DATA2 as a white data voltage may also be applied to the plurality of second sub-data lines SDL2-a and SDL2-b. In addition, the third data voltage DATA3 as a blue data voltage may also be applied to the plurality of third sub-data lines SDL3-a and SDL3-b, and the fourth data voltage DATA4 as a green data voltage may also be applied to the plurality of fourth sub-data lines SDL4-a and SDL4-b.

According to an embodiment, each of the plurality of gate lines GL1 to GL4 may be disposed on each of both opposing sides in the column direction of a row of the plurality of sub-pixels R, G, B, and W. Two gate lines GL2 and GL3 may be disposed between adjacent rows of the plurality of sub-pixels R, G, B, and W.

Specifically, referring to FIG. 3, the first gate line GL1 and the second gate line GL2 may be respectively disposed on both opposing sides in the column direction of the plurality of sub-pixels R, G, B, and W of the odd-numbered row, while the third gate line GL3 and the fourth gate line GL4 may be respectively disposed on both opposing sides in the column direction of the plurality of sub-pixels R, G, B, and W of the even-numbered row. Accordingly, the second gate line GL2 and the third gate line GL3 may be disposed between the plurality of sub-pixels R, G, B, and W arranged in the odd-numbered row and the plurality of sub-pixels R, G, B, and W arranged in the even-numbered row even.

Each of the plurality of pixels PX may be connected to the same gate line GL1 to GL4, and adjacent pixels PX among the plurality of pixels PX may be connected to different gate lines GL1 to GL4.

Specifically, referring to FIG. 3, the sub-pixels R, W, B, and G arranged in a (8k-7)th column to the (8k-4)th column of the odd-numbered row odd may be connected to the first gate line GL1, and the sub-pixels R, W, B, and G arranged in a (8k-3)th column to the 8k-th column of the odd-numbered row odd may be connected to the second gate line GL2. In addition, the sub-pixels R, W, B, and G arranged in a (8k-7)th column to the (8k-4)th column of the even-numbered row even may be connected to the third gate line GL3, and the sub-pixels R, W, B, and G arranged in a (8k-3)th column to the 8k-th column of the even-numbered row even may be connected to the fourth gate line GL4.

Each of the plurality of reference voltage lines RVL may be disposed inside one pixel PX, and each of the plurality of high potential voltage lines VDDL may be disposed between adjacent ones of the plurality of pixels PX.

Specifically, one of the plurality of reference voltage lines RVL may be disposed between the plurality of second sub-pixels W arranged in a (8k-6)th column and the plurality of third sub-pixels B arranged in a (8k-5)th column, and another thereof may be disposed between the plurality of second sub-pixels W arranged in a (8k-2)th column and the plurality of third sub-pixels B arranged in a (8k-1)th column.

One of the plurality of high potential voltage lines VDDL may be disposed between the plurality of fourth sub-pixels G arranged in a (8k-4)th column and the plurality of first sub-pixels R arranged in a (8k-3)th column, and another thereof may be disposed outside and on a left side (e.g., a first side) of the plurality of first sub-pixels R arranged in a (8k-7)th column, and still another thereof may be disposed outside and on a right side (e.g., a second side) of the plurality of fourth sub-pixels G arranged in a 8k-th column.

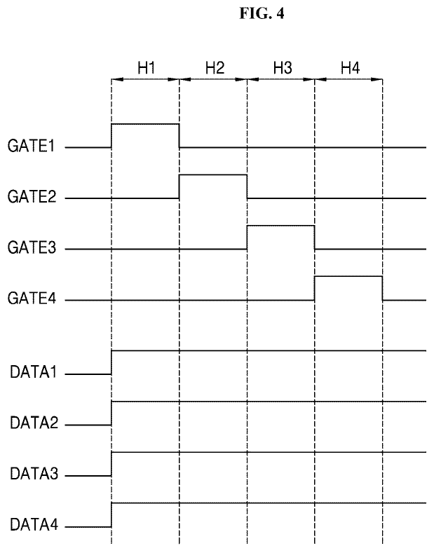

Hereinafter, a method of driving a monochromatic still screen and a method of driving a vertical pattern screen of the display device 100 according to an embodiment of the present disclosure will be described with reference to FIGS. 3 and 4.

FIG. 4 is a timing diagram of a gate voltage and a data voltage when a display device according to an embodiment of the present disclosure displays a monochromatic still screen.

As shown in FIGS. 3 and 4, the first gate voltage GATE1 is output via the first gate line GL1, the second gate voltage GATE2 is output via the second gate line GL2, the third gate voltage GATE3 is output via the third gate line GL3, and the fourth gate voltage GATE4 is output via the fourth gate line GL4.

In addition, the first data voltage DATA1 is output via the first data line DL1, the second data voltage DATA2 is output via the second data line DL2, the third data voltage DATA3 is output via the third data line DL3, and the fourth data voltage DATA4 is output via the fourth data line DL4.

As illustrated in FIG. 4, during a first horizontal period H1, the first gate voltage GATE1 is the gate high voltage, and the second gate voltage GATE2, the third gate voltage GATE3, and the fourth gate voltage GATE4 are the gate low voltages. In addition, during the first horizontal period H1, each of the first data voltage DATA1 to the fourth data voltage DATA4 may be a data voltage of a predetermined level for implementing a predetermined grayscale.

Accordingly, during the first horizontal period H1, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column are turned on.

Accordingly, during the first horizontal period H1, in the odd-numbered row odd, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 4, during a second horizontal period H2, the second gate voltage GATE2 is the gate high voltage, and the first gate voltage GATE1, the third gate voltage GATE3, and the fourth gate voltage GATE4 are the gate low voltages. In addition, even during the second horizontal period H2, each of the first data voltage DATA1 to the fourth data voltage DATA4 may be a data voltage of a predetermined level for implementing a predetermined gray level.

Accordingly, during the second horizontal period H2, all of the switching transistors respectively connected to the plurality of first sub-pixels R arranged in a (8k-3)th column, the plurality of second sub-pixels W arranged in a (8k-2)th column, the plurality of third sub-pixels B arranged in a (8k-1)th column, and the plurality of fourth sub-pixels G arranged in a 8k-th column in the odd-numbered row are turned on.

Accordingly, during the second horizontal period H2, in the odd-numbered row odd, the first data voltage DATA1 may be charged into the plurality of first sub-pixels R arranged in a (8k-3)th column, the second data voltage DATA2 may be charged into the plurality of second sub-pixels W arranged in a (8k-2)th column, the third data voltage DATA3 may be charged into the plurality of third sub-pixels B arranged in a (8k-1)th column, and the fourth data voltage DATA4 may be charged into the plurality of fourth sub-pixels G arranged in a 8k-th column.

As illustrated in FIG. 4, during a third horizontal period H3, the third gate voltage GATE3 is the gate high voltage, and the first gate voltage GATE1, the second gate voltage GATE2, and the fourth gate voltage GATE4 are the gate low voltages. In addition, even during the third horizontal period H3, each of the first data voltage DATA1 to the fourth data voltage DATA4 may be a data voltage of a predetermined level for implementing a predetermined grayscale.

Accordingly, during the third horizontal period H3, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column in the even-numbered row even are turned on.

Accordingly, during the third horizontal period H3, in the even-numbered row even, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 4, during a fourth horizontal period H4, the fourth gate voltage GATE4 is the gate high voltage, and the first gate voltage GATE1, the second gate voltage GATE2, and the third gate voltage GATE3 are the gate low voltages. In addition, even during the third horizontal period H3, each of the first data voltage DATA1 to the fourth data voltage DATA4 may be a data voltage of a predetermined level for implementing a predetermined grayscale.

Accordingly, during the fourth horizontal period H4, all of the switching transistors respectively connected to the plurality of first sub-pixels R arranged in a (8k-3)th column, the plurality of second sub-pixels W arranged in a (8k-2)th column, the plurality of third sub-pixels B arranged in a (8k-1)th column, and the plurality of fourth sub-pixels G arranged in a 8k-th column in the even-numbered row even are turned on.

Accordingly, during the fourth horizontal period H4, in the even-numbered row even, the first data voltage DATA1 may be charged into the plurality of first sub-pixels R arranged in a (8k-3)th column, the second data voltage DATA2 may be charged into the plurality of second sub-pixels W arranged in a (8k-2)th column, the third data voltage DATA3 may be charged into the plurality of third sub-pixels B arranged in a (8k-1)th column, and the fourth data voltage DATA4 may be charged into the plurality of fourth sub-pixels G arranged in a 8k-th column.

As described above, when the display device 100 according to an embodiment of the present disclosure displays the monochromatic still screen, each of the first to fourth data voltages DATA1 to DATA4 may have the same level during the first to fourth horizontal periods H1 to H4, that is, during one frame. Accordingly, each of the first to fourth data voltages DATA1 to DATA4 is maintained at a constant data voltage level during one frame. That is, the data voltage change (data transition) may not occur during one frame.

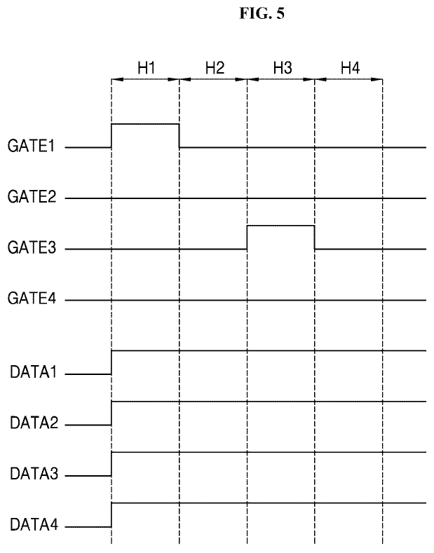

FIG. 5 is a timing diagram for a gate voltage and a data voltage when a display device according to an embodiment of the present disclosure displays a vertical pattern screen.

As illustrated in FIG. 5, during the first horizontal period H1, the first gate voltage GATE1 is a gate high voltage, and the second gate voltage GATE2, the third gate voltage GATE3, and the fourth gate voltage GATE4 are gate low voltages. In addition, during the first horizontal period H1, each of the first data voltage DATA1 to the fourth data voltage DATA4 may be a data voltage of a predetermined level for implementing a predetermined grayscale.

Accordingly, during the first horizontal period H1, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column in the odd-numbered row odd are turned on.

Accordingly, during the first horizontal period H1, in the odd-numbered row odd, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 5, during the second horizontal period H2, all of the first gate voltage GATE1, the second gate voltage GATE2, the third gate voltage GATE3, and the fourth gate voltage GATE4 are gate low voltages. In addition, even during the second horizontal period H2, each of the first data voltage DATA1 to the fourth data voltage DATA4 may be a data voltage of a predetermined level for implementing a predetermined gray level.

Accordingly, during the second horizontal period H2, all of the switching transistors respectively connected to all sub-pixels are turned off. Accordingly, during the second horizontal period H2, in the odd-numbered row odd, the first data voltage DATA1 is not charged into the plurality of first sub-pixels R arranged in a (8k-3)th column, the second data voltage DATA2 is not charged into the plurality of second sub-pixels W arranged in a (8k-2)th column, the third data voltage DATA3 is not charged into the plurality of third sub-pixels B arranged in a (8k-1)th column, and the fourth data voltage DATA4 is not charged into the plurality of fourth sub-pixels G arranged in a 8k-th column.

As illustrated in FIG. 5, during the third horizontal period H3, the third gate voltage GATE3 is the gate high voltage, and the first gate voltage GATE1, the second gate voltage GATE2, and the fourth gate voltage GATE4 are the gate low voltages. In addition, even during the third horizontal period H3, each of the first data voltage DATA1 to the fourth data voltage DATA4 may be a data voltage of a predetermined level for implementing a predetermined grayscale.

Accordingly, during the third horizontal period H3, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column in the even-numbered row even are turned on.

Accordingly, during the third horizontal period H3, in the even-numbered row even, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 5, during the fourth horizontal period H4, all of the first gate voltage GATE1, the second gate voltage GATE2, the third gate voltage GATE3, and the fourth gate voltage GATE4 are gate low voltages. In addition, even during the fourth horizontal period H4, each of the first data voltage DATA1 to the fourth data voltage DATA4 may be a data voltage of a predetermined level for implementing a predetermined grayscale.

Accordingly, during the fourth horizontal period H4, all switching transistors connected to all sub-pixels SP are turned off. Accordingly, during the fourth horizontal period H4, in the even-numbered row even, the first data voltage DATA1 may not be charged into the plurality of first sub-pixels R arranged in a (8k-3)th column, the second data voltage DATA2 may not be charged into the plurality of second sub-pixels W arranged in a (8k-2)th column, the third data voltage DATA3 may not be charged into the plurality of third sub-pixels B arranged in a (8k-1)th column, and the fourth data voltage DATA4 may not be charged into the plurality of fourth sub-pixels G arranged in a 8k-th column.

As described above, when the display device 100 according to an embodiment of the present disclosure displays the vertical pattern screen, each of the first data voltage DATA1 to the fourth data voltage DATA4 may be at the same level during the first to fourth horizontal periods H 4, that is, during one frame. Accordingly, each of the first data voltage DATA1 to the fourth data voltage DATA4 is maintained at a constant data voltage during one frame.

In a conventional display device, two sub-pixels emitting light of different colors are connected to one data line. Accordingly, in the conventional display device, the data voltage applied to the data line should be a data voltage corresponding to a plurality of colors, change in the data voltage (data transition) is essential. That is, data voltage change (data transition) may occur even within one horizontal period, and data voltage change (data transition) should occur within at least one frame.

Accordingly, when the data voltage change (data transition) frequently occurs, the data voltage is not completely charged during one horizontal period. Further, when the data voltage change (data transition) frequently occurs, the heat generation from the data driver supplying the data voltage is increased.

On the other hand, in the display device according to an embodiment of the present disclosure, each of the plurality of data lines DL1, DL2, DL3, and DL4 may divide into a plurality of sub-data lines SDL1-a and SDL1-b, SDL2-a and SDL2-b, SDL3-a and SDL3-b, or SDL4-a and SDL4-b. The plurality of sub-data lines SDL1-a and SDL1-b, SDL2-a and SDL2-b, SDL3-a and SDL3-b, or SDL4-a and SDL4-b may be connected to the sub-pixels R, G, B, or W emitting light of the same color. Accordingly, in the display device according to an embodiment of the present disclosure, the plurality of data lines need to output the data voltage corresponding to one color. Thus, when a single-color still screen or a vertical pattern screen is implemented, the data voltage change (data transition) does not occur during one frame.

Accordingly, the data voltage may be completely charged during one frame, thereby solving the problem of incomplete charging of the data voltage in the conventional display device. In addition, since the data voltage is kept constant during one frame, the heat generation phenomenon form the data driver supplying the data voltage may also be reduced.

Moreover, even when the display device displays the vertical pattern screen, the data voltage change (data transition) does not occur during one frame, so that the burden of the data driver may be minimized when the pattern vertical pattern screen is implemented.

Hereinafter, a display device according to another embodiment of the present disclosure will be described.

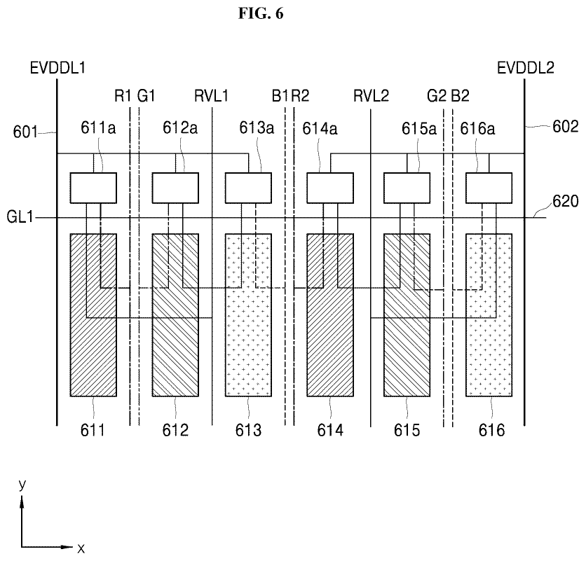

FIG. 6 is an example diagram illustrating pixel arrangement when the display device according to an embodiment of the present disclosure operates in a single rate driving (SRD) driving manner.

The display device may operate in various driving manners such as a single rate driving (SRD) manner, a double rate driving (DRD) manner, etc.

The SRD (single rate driving) driving scheme is a driving scheme in which each sub-pixel is connected to each data line and receives a data voltage therefrom and operates based on the data voltage. For example, when each pixel of the display panel 110 includes three sub-pixels R, G, and B, the data driver 120 may be connected to six sub-pixels of two pixels via six data lines, respectively.

According to the SRD (single rate driving) driving scheme, the data driver 120 may individually and independently drive the corresponding six sub-pixels via the six data lines. The data driver 120 may supply different data voltages to six data lines.

The DRD driving scheme is a driving scheme in which six data lines are grouped into three pairs and the sub-pixels operate based on each pair of data lines. For example, the data driver 120 may simultaneously drive red sub-pixels respectively included in first and second pixels via a data line connected to the red sub-pixel included in the first pixel and a data line connected to the red sub-pixel included in the second pixel.

As described above, the driving scheme may be changed based on a structure in which each sub-pixel and the data line are connected to each other.

Referring to FIG. 6, in the display panel 110, a first pixel may include three sub-pixels 611, 612, and 613, and a second pixel may include three sub-pixels 614, 615, and 616.

According to an embodiment, a first driving circuit 611a may be disposed on one side (upper side or first side in a plan view of the drawing) in the column direction or the y-axis direction of the first sub-pixel R 611, a second driving circuit 612a may be disposed on one side (upper side in the drawing) in the column direction or the y-axis direction of the second sub-pixel G 612, and the third driving circuit 613a may be disposed on one side (upper side in the drawing) in the column direction or the y-axis direction of the third sub-pixel B 613.

According to an embodiment, a fourth driving circuit 614a may be disposed on one side (upper side in the drawing) in the column direction or the y-axis direction of the fourth sub-pixel R 614, a fifth driving circuit 615a may be disposed on one side (upper side in the drawing) in the column direction or the y-axis direction of the fifth sub-pixel G 615, and a sixth driving circuit 616a may be disposed on one side (upper side in the drawing) in the column direction or the y-axis direction of the sixth sub-pixel B 616.

Alternatively, the driving circuits 611a, 612a, 613a, 614a, 615a, and 616a may be disposed on the other sides (lower sides or second in the drawing) in the column direction or the y-axis direction of the first to sixth sub-pixels 611, 612, 613, 614, 615, and 616, respectively. The display panel 110 according to the present disclosure is not limited thereto.

According to an embodiment, the high potential voltage is applied to the first driving circuit 611a of the first sub-pixel R 611, the second driving circuit 612a of the second sub-pixel G 612, and the third driving circuit 613a of the third sub-pixel B 613 via a first high potential voltage line EVDDL1 601 to operate the first sub-pixel R 611, the second sub-pixel G 612, and the third sub-pixel B 613.

FIG. 6 illustrates that the first sub-pixel R 611, the second sub-pixel G 612, and the third sub-pixel B 613 are disposed on the right side (in the x-axis direction or row direction) of the first high potential voltage line EVDDL1 601, and the first high potential voltage line EVDDL1 is connected to the first sub-pixel R 611, the second sub-pixel G 612, and the third sub-pixel B 613.

However, although not shown in FIG. 6, three sub-pixels R, G, and B are also disposed on the left side (in the x-axis direction or row direction) of the first high potential voltage line EVDDL1 601, and the first high potential voltage line EVDDL1 is also connected to the three sub-pixels R, G, and B.

As described above, the first high potential voltage line EVDDL1 601 is connected to three sub-pixels disposed on each of the left and right sides of the first high potential voltage lines EVDDL1 601. That is, the first high potential voltage line EVDDL1 601 may be connected to a total of six sub-pixels, and the high potential voltage may be applied to each driving circuit of each of the six sub-pixels via the first high potential voltage line EVDDL1 601.

According to an embodiment, the high potential voltage is applied to the fourth driving circuit 614a of the fourth sub-pixel R 614, the fifth driving circuit 615a of the fifth sub-pixel G 615, and the sixth driving circuit 616a of the sixth sub-pixel B 616 via a second high potential voltage line EVDDL2 602 to operate the fourth sub-pixel R 614, the fifth sub-pixel G 615, and the sixth sub-pixel B 616.

FIG. 6 illustrates that the fourth sub-pixel R 614, the fifth sub-pixel G 615, and the sixth sub-pixel B 616 are disposed on the left side (in the x-axis direction or row direction) of the second high potential voltage line EVDDL2 602, and the second high potential voltage line EVDDL2 602 is connected to the fourth sub-pixel R 614, the fifth sub-pixel G 615, and the sixth sub-pixel B 616.

However, although not shown in FIG. 6, three sub-pixels R, G, and B are also disposed on the right side (in the x-axis direction or row direction) of the second high potential voltage line (EVDDL2) 602, and the second high potential voltage line (EVDDL2) 602 is also connected to the three sub-pixels R, G, and B.

As described above, the second high potential voltage line EVDDL2 602 is connected to the three sub-pixels on each of the left and right sides of the second high potential voltage line EVDDL2. That is, the second high-potential voltage line EVDDL2 602 are connected to a total of six sub-pixels, and the high-potential voltage may be applied to the driving circuits of each of the six sub-pixels via the second high-potential voltage line EVDDL2 602.

According to an embodiment, a first gate line 620 is disposed between an array of the first to sixth sub-pixels 611, 612, 613, 614, 615, and 616 and an array of the first to sixth driving circuits 611a, 612a, 613a, 614a, 615a, and 616a so as to supply a gate signal to the first to sixth sub-pixels 611, 612, 613, 614, 615, and 616.

According to an embodiment, a first reference voltage line RVL1 is disposed between the second sub-pixel 612 and the third sub-pixel 613, and a second reference voltage line RVL2 is disposed between the fourth sub-pixel 614 and the fifth sub-pixel 615.

However, in the SRD (single rate driving) driving scheme based on the three sub-pixels, one high potential voltage line is used to drive the six sub-pixels. Thus, when the DRD based on the three sub-pixels is designed in the same arrangement as in the SRD scheme, a column line defect between the odd-numbered row and the even-numbered row may occur in a process due to the left-right asymmetry.

In addition, in the SRD structure, when an overlay between an odd-numbered row and an even-numbered row of the sub-pixels emitting light of the same color is shifted due to a process variation, the two pixels are shifted in the same direction, and thus, a difference between a parasitic capacitance variation of the odd-numbered row and a parasitic capacitance variation of the even-numbered row is small. However, in the DRD structure, since the driving circuits for driving the pixels are arranged in the row direction in the staggered manner, a difference between the arrangement of the storage capacitor Cst and the gate line GL and the arrangement of another storage capacitor and the gate line occurs due to the overlay variation. For this reason, a low line defect between the odd-numbered row and the even-numbered row due to a difference between the parasitic capacitance of the pixel of the odd-numbered row and the parasitic capacitance of the pixel of the even-numbered row occurs.

In order to solve this problem, in the display panel 110 according to the present disclosure, the high potential voltage line is additionally disposed between adjacent ones of the plurality of pixels.

Each pixel of the display panel 110 according to the present disclosure may be composed of a plurality of sub-pixels, and may generally include three sub-pixels that emit red, green, and blue light, respectively. However, the present disclosure is not limited thereto, and each pixel may further include one sub-pixel that emits white light. In the present disclosure, the first sub-pixel, the second sub-pixel, and the third sub-pixel are configured to emit three light beams of red, green, and blue colors, respectively. The first sub-pixel may be a sub-pixel emitting light of one of red, green, and blue, the second sub-pixel may be a sub-pixel emitting light of another of red, green, and blue, and the third sub-pixel may be a sub-pixel emitting light of the other of red, green, and blue lights.

The first to third sub-pixels may be arranged along a first direction (e.g., hereinafter, referred to as the row direction or an “x-axis direction” to help understanding of description). Each of the first to third sub-pixels may be oriented such that a short side thereof extends in the x-axis direction and a long side thereof extends in a second direction (e.g., hereinafter, referred to as the column direction or “y-axis direction” for better understanding of the description) intersecting the first direction.

As used herein, the x-axis or first direction and the y-axis or second direction are examples of directions intersecting each other. The definition thereof is not used to limit the present disclosure.

Therefore, the x-axis or first and y-axis or second directions described in the present disclosure should not be simply limited to directions intersecting with each other at a right angle. The x-axis or first and y-axis or second directions intersecting each other at any angle should be interpreted as being included in the present disclosure.

The high potential voltage line EVDD may extend along the y-axis direction while being disposed on one side (e.g., left side) in the x-axis direction of the pixel. The data line and the sensing line VREF may extend in the y-axis direction and in parallel with the high potential voltage line EVDD while being disposed on the other side (e.g., right side) in the x-axis direction of the pixel.

Hereinafter, an example in which a high potential voltage line is additionally disposed between adjacent ones of a plurality of pixels according to various embodiments of the present disclosure will be described.

### First Embodiment

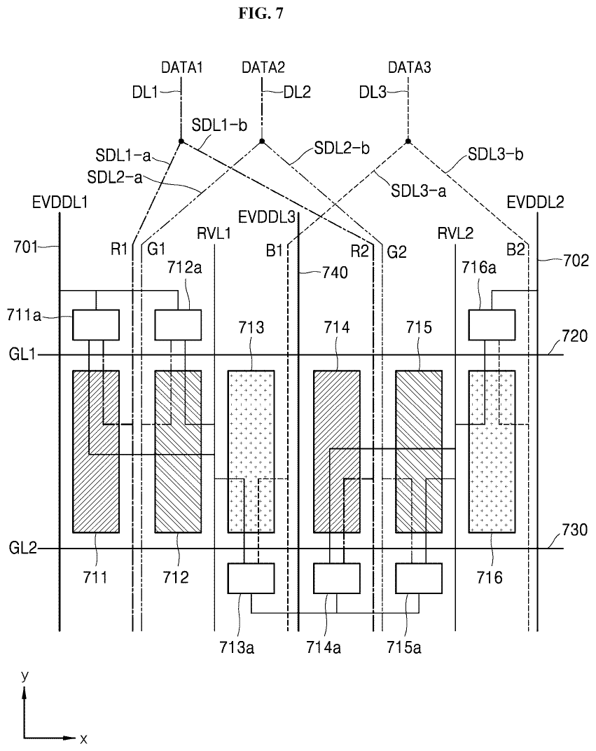

FIG. 7 is a first example diagram in which a high potential voltage line is additionally disposed between adjacent ones of a plurality of pixels according to an embodiment of the present disclosure.

Referring to FIG. 7, each of the plurality of data lines DL1, DL2, and DL3 may divide into a plurality of sub-data lines SDL1-a, SDL1-b, SDL2-a, SDL2-b, SDL3-a, and SDL3-b.

Specifically, the first data line DL1 may divide into a plurality of first sub-data lines SDL1-a and SDL1-b, the second data line DL2 may divide into a plurality of second sub-data lines SDL2-a and SDL2-b, and the third data line DL3 may divide into a plurality of third sub-data lines SDL3-a and SDL3-b.

According to an embodiment, the first sub-data lines SDL1-a and SDL1-b may include a (1-a)th sub-data line SDL1-a and a (1-b)th sub-data line SDL1-b, the second sub-data lines SDL2-aand SDL2-b may include a (2-a)th sub-data line SDL2-a and a (2-b)th sub-data line SDL2-b, and the third sub-data lines SDL3-a and SDL3-b may include a (3-a)th sub-data line SDL3-a and a (3-b)th sub-data line SDL3-b.

Each of the plurality of high potential voltage lines EVDDL may be disposed between adjacent ones of the plurality of pixels PX.

FIG. 7 illustrates a pixel row having a first pixel and a second pixel that is adjacent to the first pixel in the pixel row. The first pixel of the display panel 110 may include three sub-pixels 711, 712, and 713, and the second pixel may include three sub-pixels 714, 715, and 716.

According to an embodiment, a first driving circuit 711a is disposed on one side (upper side in the drawing) in the column direction or the y-axis direction of the first sub-pixel R 711 in a plan view of the display panel 110, and a second driving circuit 712a is disposed on one side (upper side in the drawing) in the column direction or the y-axis direction of the second sub-pixel G 712 in the plan view. A third driving circuit 713a may be disposed on the other side (lower side in the drawing) in the column direction or the y-axis direction of the third sub-pixel B 713 in the plan view.

According to an embodiment, a fourth driving circuit 714a is disposed on the other side (lower side in the drawing) in the column direction or the y-axis direction of the fourth sub-pixel R 714, and a fifth driving circuit 715a is disposed on the other side (lower side in the drawing) in the column direction or the y-axis direction of the fifth sub-pixel G 715. However, a sixth driving circuit 716a may be disposed on one side (upper side in the drawing) in the column direction or the y-axis direction of the sixth sub-pixel B 716.

According to an embodiment, the respective driving circuits for respectively driving the plurality of sub-pixels of the first pixel and the respective driving circuits for respectively driving the plurality of sub-pixels of the second pixel may be arranged in the row direction in the staggered manner. In other word, two of the respective driving circuits for respectively driving the plurality of sub-pixels of the first pixel may be disposed on one side (upper side in the drawing) in the column direction or the y-axis direction of the array of the sub-pixels of the first and second pixels, one of the respective driving circuits for respectively driving the plurality of sub-pixels of the first pixel may be disposed on the other side (low side in the drawing) in the column direction or the y-axis direction of the array of the sub-pixels of the first and second pixels, and then two of the respective driving circuits for respectively driving the plurality of sub-pixels of the second pixel may be disposed on the other side (lower side in the drawing) in the column direction or the y-axis direction of the array of the sub-pixels of the first and second pixels, and one of the respective driving circuits for respectively driving the plurality of sub-pixels of the second pixel may be disposed on one side (upper side in the drawing) in the column direction or the y-axis direction of the array of the sub-pixels of the first and second pixels.

Alternatively, a position of each of the driving circuits of the first to sixth sub-pixels 711, 712, 713, 714, 715, and 716 may be opposite to that in FIG. 7. The display panel 110 according to the present disclosure is not limited thereto.

According to an embodiment, the high potential voltage (e.g., a first high potential voltage) is applied to the first driving circuit 711a of the first sub-pixel R 711 and the second driving circuit 712a of the second sub-pixel G 712 via the first high potential voltage line EVDDL1 701 to operate the first sub-pixel R 711 and the second sub-pixel G 712.

FIG. 7 illustrates that the first sub-pixel R 711 and the second sub-pixel G 712 are disposed on the right side (in the x-axis direction or row direction) of a first high potential voltage line EVDDL1 701. The first high potential voltage line EVDDL1 701 is connected to the first sub-pixel R 711 and the second sub-pixel G 712. As such, the first high potential voltage line EVDDL1 701 may be disposed on the left side (e.g., the first side) in the first direction of the first pixel including the sub-pixels 711, 712, and 713 in a plan view of the display device.

However, although not shown in FIG. 7, the sub-pixel B is also disposed on the left side in the x-axis direction of the first high potential voltage line EVDDL1 701, and the first high potential voltage line EVDDL1 701 is also connected to the sub-pixel B.

As such, the first high potential voltage line EVDDL1 701 is connected to the three sub-pixels R, G, and B.

According to an embodiment, the high potential voltage (e.g., a second high potential voltage) is applied to the sixth driving circuit 716a of the sixth sub-pixel B 716 via a second high potential voltage line EVDDL2 702 to operate the sixth sub-pixel B 716.

FIG. 7 illustrates that the sixth sub-pixel B 716 is disposed on the left side (in the x-axis direction) of the second high potential voltage line EVDDL2 702 and the second high potential voltage line EVDDL2 702 is connected to the sixth sub-pixel B 716. As such, the second high potential voltage line EVDDL2 702 may be disposed in the right side (e.g., the second side) in the x-axis direction of the second pixel including the sub-pixels 714, 715, and 716 in a plan view of the display device.

However, although not shown in FIG. 7, two sub-pixels R and G are also disposed on the right side in the x-axis direction or row direction of the second high potential voltage line EVDDL2 702, and the second high potential voltage line EVDDL2 702 is also connected to the two sub-pixels R and G.

According to an embodiment, the high potential voltage (e.g., a third high potential voltage) is applied to the third driving circuit 713a of the third sub-pixel B 713, the fourth driving circuit 714a of the fourth sub-pixel R 714, and the fifth driving circuit 715a of the fifth sub-pixel G 715 via a third high potential voltage line EVDDL3 740 to operate the third sub-pixel B 713, the fourth sub-pixel R 714, and the fifth sub-pixel G 715. To this end, the third high potential voltage line EVDDL3 740 may be disposed between the first pixel including the sub-pixels 711, 712, and 713 and the second pixel including the sub-pixels 714, 715, and 716. Thus, the third high potential voltage line is on a second side (e.g., the right side) of the first pixel and a first side (e.g., the left side) of the second pixel.

According to an embodiment, a first gate line 720 is disposed between the first sub-pixel 711 and the first driving circuit 711a, between the second sub-pixel 712 and the second driving circuit 712a, and between the sixth sub-pixel 716 and the sixth driving circuit 716a to supply the gate signal to the first sub-pixel 711, the second sub-pixel 712, and the sixth sub-pixel 716.

According to an embodiment, a second gate line 730 is disposed between the third sub-pixel 713 and the third driving circuit 713a, between the fourth sub-pixel 714 and the fourth driving circuit 714a, and between the fifth sub-pixel 715 and the fifth driving circuit 715a to supply the gate signal to the third sub-pixel 713, the fourth sub-pixel 714, and the fifth sub-pixel 715.

According to an embodiment, a first reference voltage line RVL1 is disposed between the second sub-pixel 712 and the third sub-pixel 713, and a second reference voltage line RVL2 is disposed between the fifth sub-pixel 715 and the sixth sub-pixel 716.

As described above, according to the first embodiment of the present disclosure, in the SRD (single rate driving) driving scheme based on three sub-pixels, the third high potential voltage line EVDD3 740 is disposed between the adjacent pixels so that the driving circuits of the first and second pixels are arranged so as to be asymmetrical with each other around the third high potential voltage line EVDD3 740, thereby suppressing the column line defect occurring between the odd-numbered row and the even-numbered row during the process due to the left-right asymmetry.

A display panel according to the first embodiment includes a first pixel including a plurality of sub-pixels; a second pixel including a plurality of sub-pixels, wherein the first pixel and the second pixel are adjacent to each other in a row direction; a first high potential voltage line disposed on one side in the row direction of the first pixel; a second high potential voltage line disposed on the other side in the row direction of the second pixel, wherein the one side and the other side are opposite to each other in the row direction; and a third high potential voltage line disposed between the first pixel and the second pixel.

According to the first embodiment of the display panel of the present disclosure, the display panel further comprises each driving circuit configured to drive each of the plurality of sub-pixels of each of the first and second pixels, wherein each driving circuit is disposed on one or the other of both opposing sides in a column direction of each corresponding sub-pixel such that at least one of the driving circuits corresponding to the sub-pixels of the first pixel and at least one of the driving circuits corresponding to the sub-pixels of the second pixel are arranged in the row direction in a staggered manner.

According to the first embodiment of the display panel of the present disclosure, the first pixel includes first to third sub-pixels sequentially arranged in the row direction, wherein the display panel further comprises first to third driving circuits configured to drive the first to third sub-pixels, respectively, wherein the first driving circuit is disposed on one of both opposing sides in a column direction of the first sub-pixel, wherein the second driving circuit is disposed on one of both opposing sides in the column direction of the second sub-pixel, wherein the third driving circuit is disposed on the other of both opposing sides in the column direction of the third sub-pixel.

According to the first embodiment of the display panel of the present disclosure, the second pixel includes fourth to sixth sub-pixels sequentially arranged in the row direction, wherein the display panel further comprises fourth to sixth driving circuits configured to drive the fourth to sixth sub-pixels, respectively, wherein the fourth driving circuit is disposed on the other of both opposing sides in the column direction of the fourth sub-pixel, wherein the fifth driving circuit is disposed on the other of both opposing sides in the column direction of the fifth sub-pixel, wherein the sixth driving circuit is disposed on one of both opposing sides in the column direction of the sixth sub-pixel.

According to the first embodiment of the display panel of the present disclosure, the display panel further comprises a plurality of gate lines disposed to supply a gate signal to the first pixel and the second pixel, wherein the plurality of gate lines include a first gate line disposed between the first sub-pixel and the first driving circuit, between the second sub-pixel and the second driving circuit, and between the sixth sub-pixel and the sixth driving circuit.

According to the first embodiment of the display panel of the present disclosure, the plurality of gate lines include a second gate line disposed between the third sub-pixel and the third driving circuit, between the fourth sub-pixel and the fourth driving circuit, and between the fifth sub-pixel and the fifth driving circuit.

According to the first embodiment of the display panel of the present disclosure, the gate signal is supplied to each of the first driving circuit, the second driving circuit, and the sixth driving circuit applied via the first gate line to operate each of the first sub-pixel, the second sub-pixel, and the sixth sub-pixel.

According to the first embodiment of the display panel of the present disclosure, the gate signal is supplied to each of the third driving circuit, the fourth driving circuit, and the fifth driving circuit via the second gate line to operate each of the third sub-pixel, the fourth sub-pixel, and the fifth sub-pixel.

According to the first embodiment of the display panel of the present disclosure, the third high potential voltage line is disposed between the third sub-pixel and the fourth sub-pixel.

According to the first embodiment of the display panel of the present disclosure, the first high potential voltage line applies a high potential voltage to the first driving circuit and the second driving circuit, wherein the second high potential voltage line applies a high potential voltage to the sixth driving circuit, wherein the third high potential voltage line applies a high potential voltage to the third driving circuit, the fourth driving circuit, and the fifth driving circuit.

### Second Embodiment

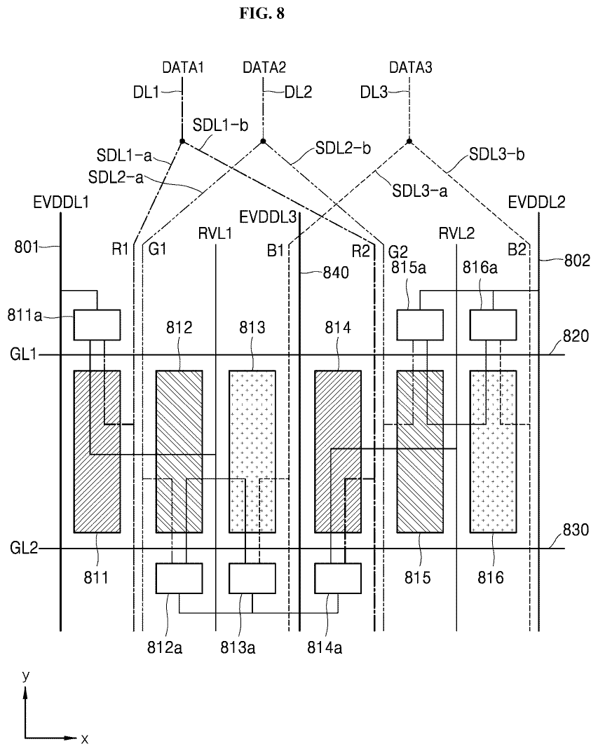

FIG. 8 is a second example diagram in which a high potential voltage line is additionally disposed between adjacent ones of a plurality of pixels according to an embodiment of the present disclosure.

Referring to FIG. 8, each of the plurality of data lines DL1, DL2, and DL3 may divide into a plurality of sub-data lines SDL1-a, SDL1-b, SDL2-a, SDL2-b, SDL3-a, and SDL3-b.

Specifically, the first data line DL1 may divide into a plurality of first sub-data lines SDL1-a and SDL1-b, the second data line DL2 may divide into a plurality of second sub-data lines SDL2-a and SDL2-b, and the third data line DL3 may divide into a plurality of third sub-data lines SDL3-a and SDL3-b.

According to an embodiment, the first sub-data lines SDL1-a and SDL1-b may include a (1-a)th sub-data line SDL1-a and a (1-b)th sub-data line SDL1-b, the second sub-data lines SDL2-a and SDL2-b may include a (2-a)th sub-data line SDL2-a and a (2-b)th sub-data line SDL2-b, and the third sub-data lines SDL3-a and SDL3-b may include a (3-a)th sub-data line SDL3-a and a (3-b)th sub-data line SDL3-b.

Each of the plurality of high potential voltage lines EVDDL may be disposed between adjacent ones of the plurality of pixels PX.

FIG. 8 illustrates a pixel row having a first pixel and a second pixel that is adjacent to the first pixel in the pixel row. The first pixel of the display panel 110 may include three sub-pixels 811, 812, and 813, and the second pixel may include three sub-pixels 814, 815, and 816.

According to an embodiment, a first driving circuit 811a is disposed on one side (upper side in the drawing) in the column direction or the y-axis direction of the first sub-pixel R 811. A second driving circuit 812a may be disposed on the other side (lower side in the drawing) in the column direction or the y-axis direction of the second sub-pixel G 812, and a third driving circuit 813a may be disposed on the other side (lower side in the drawing) in the column direction or the y-axis direction of the third sub-pixel B 813.

According to an embodiment, a fourth driving circuit 814a is disposed on the other side (lower side in the drawing) in the column direction or the y-axis direction of the fourth sub-pixel R 814. A fifth driving circuit 815a may be disposed on one side (upper side in the drawing) in the column direction or the y-axis direction of the fifth sub-pixel G 815, and a sixth driving circuit 816a may be disposed on one side (upper side in the drawing) in the column direction or the y-axis direction of the sixth sub-pixel B 816.

According to an embodiment, the respective driving circuits for respectively driving the plurality of sub-pixels of the first pixel and the respective driving circuits for respectively driving the plurality of sub-pixels of the second pixel may be arranged in the row direction in the staggered manner. In other word, one of the respective driving circuits for respectively driving the plurality of sub-pixels of the first pixel may be disposed on one side (upper side in the drawing) in the column direction or the y-axis direction of the array of the sub-pixels of the first and second pixels, two of the respective driving circuits for respectively driving the plurality of sub-pixels of the first pixel may be disposed on the other side (low side in the drawing) in the column direction or the y-axis direction of the array of the sub-pixels of the first and second pixels, and then one of the respective driving circuits for respectively driving the plurality of sub-pixels of the second pixel may be disposed on the other side (lower side in the drawing) in the column direction or the y-axis direction of the array of the sub-pixels of the first and second pixels, and two of the respective driving circuits for respectively driving the plurality of sub-pixels of the second pixel may be disposed on one side (upper side in the drawing) in the column direction or the y-axis direction of the array of the sub-pixels of the first and second pixels.

Alternatively, a position of each of the driving circuits of the first to sixth sub-pixels 811, 812, 813, 814, 815, and 816 may be opposite to that in FIG. 8. The display panel 110 according to the present disclosure is not limited thereto.

According to an embodiment, the high potential voltage is applied to the first driving circuit 811a of the first sub-pixel R 811 via a first high potential voltage line EVDDL1 801 to operate the first sub-pixel R 811.

FIG. 8 illustrates that the first sub-pixel R 811 is disposed on the right side (in the x-axis direction or row direction) of the first high potential voltage line EVDDL1 801, and the first high potential voltage line EVDDL1 801 is connected to the first sub-pixel R 811. As such, the first high potential voltage line EVDDL1 801 may be disposed on one side (e.g., left side) in the x-axis direction of the first pixel including the sub-pixels 811, 812, and 813.

However, although not shown in FIG. 8, the sub-pixels G and B are also disposed on the left side in the x-axis direction of the first high potential voltage line EVDDL1 and the first high potential voltage line EVDDL1 is also connected to the sub-pixels G and B.

As such, the first high potential voltage line EVDDL1 is connected to the three sub-pixels R, G, and B.

According to an embodiment, the high potential voltage is applied to the fifth driving circuit 815a of the fifth sub-pixel G 815 and the sixth driving circuit 816a of the sixth sub-pixel B 816 via a second high potential voltage line EVDDL2 802 to operate the fifth sub-pixel G 815 and the sixth sub-pixel B 816.

FIG. 8 illustrates that the fifth sub-pixel G 815 and the sixth sub-pixel B 816 are disposed on the left side in the x-axis direction of the second high potential voltage line EVDDL2 802, and the second high potential voltage line EVDDL2 is connected to the fifth sub-pixel G 815 and the sixth sub-pixel B 816. As such, the second high potential voltage line EVDDL2 802 may be disposed on the other side (e.g., right side) in the x-axis direction of the second pixel including the sub-pixels 814, 815, and 816.

However, although not shown in FIG. 8, one sub-pixel R is also disposed on the right side (in the x-axis direction or row direction) of the second high potential voltage line EVDDL2, and the second high potential voltage line EVDDL2 802 is also connected to one sub-pixel R.

According to an embodiment, the high potential voltage is applied to the second driving circuit 812a of the second sub-pixel G 812, the third driving circuit 813a of the third sub-pixel B 813, and the fourth driving circuit 814a of the fourth sub-pixel R 814 via a third high potential voltage line EVDDL3 840 to operate the second sub-pixel G 812, the third sub-pixel B 813, and the fourth sub-pixel R 814. To this end, the third high potential voltage line EVDDL3 840 may be disposed between the first pixel including the sub-pixels 811, 812, and 813 and the second pixel including the sub-pixels 814, 815, and 816.

According to an embodiment, a first gate line 820 is disposed between the first sub-pixel 811 and the first driving circuit 811a, between the fifth sub-pixel 815 and the fifth driving circuit 815a, and between the sixth sub-pixel 816 and the sixth driving circuit 816a to supply the gate signal to the first sub-pixel 811, the fifth sub-pixel 815, and the sixth sub-pixel 816.

According to an embodiment, the second gate line 830 is disposed between the second sub-pixel 812 and the second driving circuit 812a, between the third sub-pixel 813 and the third driving circuit 813a, and between the fourth sub-pixel 814 and the fourth driving circuit 814a to supply the gate signal to the second sub-pixel 812, the third sub-pixel 813, and the fourth sub-pixel 814.

According to an embodiment, the first reference voltage line RVL1 is disposed between the second sub-pixel 812 and the third sub-pixel 813, and the second reference voltage line RVL2 is disposed between the fifth sub-pixel 815 and the sixth sub-pixel 816.

As described above, according to the second embodiment of the present disclosure, in the SRD (single rate driving) driving scheme based on three sub-pixels, the third high potential voltage line EVDD3 840 is disposed between the adjacent pixels so that the driving circuits of the first and second pixels are arranged so as to be asymmetrical with each other around the third high potential voltage line EVDD3 840, thereby suppressing the column line defect occurring between the odd-numbered row and the even-numbered row during the process due to the left-right asymmetry.

A display panel according to the second embodiment includes a first pixel including a plurality of sub-pixels; a second pixel including a plurality of sub-pixels, wherein the first pixel and the second pixel are adjacent to each other in a row direction; a first high potential voltage line disposed on one side in the row direction of the first pixel; a second high potential voltage line disposed on the other side in the row direction of the second pixel, wherein the one side and the other side are opposite to each other in the row direction; and a third high potential voltage line disposed between the first pixel and the second pixel.

According to the second embodiment of the display panel of the present disclosure, the display panel further comprises each driving circuit configured to drive each of the plurality of sub-pixels of each of the first and second pixels, wherein each driving circuit is disposed on one or the other of both opposing sides in a column direction of each corresponding sub-pixel such that at least one of the driving circuits corresponding to the sub-pixels of the first pixel and at least one of the driving circuits corresponding to the sub-pixels of the second pixel are arranged in the row direction in a staggered manner.

According to the second embodiment of the display panel of the present disclosure, the first pixel includes first to third sub-pixels sequentially arranged in the row direction, wherein the display panel further comprises first to third driving circuits configured to drive the first to third sub-pixels, respectively, wherein the first driving circuit is disposed on one of both opposing sides in a column direction of the first sub-pixel, wherein the second driving circuit is disposed on the other of both opposing sides in the column direction of the second sub-pixel, wherein the third driving circuit is disposed on the other of both opposing sides in the column direction of the third sub-pixel.

According to the second embodiment of the display panel of the present disclosure, the second pixel includes fourth to sixth sub-pixels sequentially arranged in the row direction, wherein the display panel further comprises fourth to sixth driving circuits configured to drive the fourth to sixth sub-pixels, respectively, wherein the fourth driving circuit is disposed on the other of both opposing sides in the column direction of the fourth sub-pixel, wherein the fifth driving circuit is disposed on one of both opposing sides in the column direction of the fifth sub-pixel, wherein the sixth driving circuit is disposed on one of both opposing sides in the column direction of the sixth sub-pixel.

According to the second embodiment of the display panel of the present disclosure, the display panel further comprises a plurality of gate lines disposed to supply a gate signal to the first pixel and the second pixel, wherein the plurality of gate lines include a first gate line disposed between the first sub-pixel and the first driving circuit, between the fifth sub-pixel and the fifth driving circuit, and between the sixth sub-pixel and the sixth driving circuit.

According to the second embodiment of the display panel of the present disclosure, the plurality of gate lines include a second gate line disposed between the second sub-pixel and the second driving circuit, between the third sub-pixel and the third driving circuit, and between the fourth sub-pixel and the fourth driving circuit.

According to the second embodiment of the display panel of the present disclosure, the first high potential voltage line applies a high potential voltage to the first driving circuit, wherein the second high potential voltage line applies a high potential voltage to the fifth driving circuit and the sixth driving circuit, wherein the third high potential voltage line applies a high potential voltage to the second driving circuit, the third driving circuit, and the fourth driving circuit.

### Third Embodiment

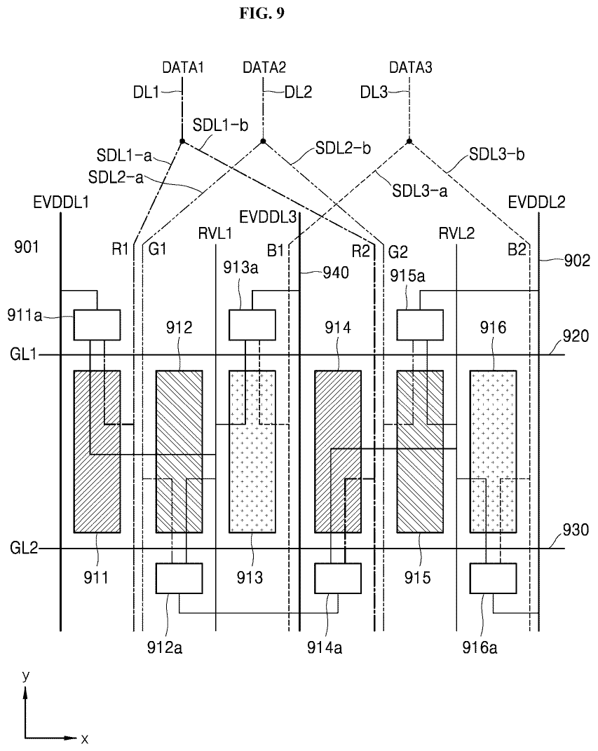

FIG. 9 is a third example diagram in which a high potential voltage line is additionally disposed between adjacent ones of a plurality of pixels according to an embodiment of the present disclosure.

Referring to FIG. 9, each of the plurality of data lines DL1, DL2, and DL3 may divide into a plurality of sub-data lines SDL1-a, SDL1-b, SDL2-a, SDL2-b, SDL3-a, and SDL3-b.

Specifically, the first data line DL1 may divide into a plurality of first sub-data lines SDL1-a and SDL1-b, the second data line DL2 may divide into a plurality of second sub-data lines SDL2-a and SDL2-b, and the third data line DL3 may divide into a plurality of third sub-data lines SDL3-a and SDL3-b.

According to an embodiment, the first sub-data lines SDL1-a and SDL1-b may include a (1-a)th sub-data line SDL1-a and a (1-b)th sub-data line SDL1-b, the second sub-data lines SDL2-a and SDL2-b may include a (2-a)th sub-data line SDL2-a and a (2-b)th sub-data line SDL2-b, and the third sub-data lines SDL3-a and SDL3-b may include a (3-a)th sub-data line SDL3-a and a (3-b)th sub-data line SDL3-b.

Each of the plurality of high potential voltage lines EVDDL may be disposed between adjacent ones of the plurality of pixels PX.

FIG. 9 illustrates a pixel row having a first pixel and a second pixel that is adjacent to the first pixel in the pixel row. The first pixel of the display panel 110 may include three sub-pixels 911, 912, and 913, and the second pixel may include three sub-pixels 914, 915, and 916.

According to an embodiment, a first driving circuit 911a may be disposed on one side (upper side in the drawing) in the column direction or the y-axis direction of the first sub-pixel R 911, a second driving circuit 912a may be disposed on one side (upper side in the drawing) in the column direction or the y-axis direction of the second sub-pixel G 912, and a third driving circuit 913a may be disposed on one side (upper side in the drawing) in the column direction or the y-axis direction of the third sub-pixel B 913.

According to an embodiment, a fourth driving circuit 914a is disposed on the other side (lower side in the drawing) in the column direction or the y-axis direction of the fourth sub-pixel R 914. In addition, a fifth driving circuit 915a may be disposed on one side (upper side in the drawing) in the column direction or the y-axis direction of the fifth sub-pixel G 915, and a sixth driving circuit 916a may be disposed on the other side (lower side in the drawing) in the column direction or the y-axis direction of the sixth sub-pixel B 916.

According to an embodiment, the respective driving circuits for respectively driving the plurality of sub-pixels of the first pixel and the respective driving circuits for respectively driving the plurality of sub-pixels of the second pixel may be arranged in the row direction in the staggered manner. In other word, one of the respective driving circuits for respectively driving the plurality of sub-pixels of the first pixel may be disposed on one side (upper side in the drawing) in the column direction or the y-axis direction of the array of the sub-pixels of the first and second pixels, another of the respective driving circuits for respectively driving the plurality of sub-pixels of the first pixel may be disposed on the other side (low side in the drawing) in the column direction or the y-axis direction of the array of the sub-pixels of the first and second pixels, the other of the respective driving circuits for respectively driving the plurality of sub-pixels of the first pixel may be disposed on one side (upper side in the drawing) in the column direction or the y-axis direction of the array of the sub-pixels of the first and second pixels, and one of the respective driving circuits for respectively driving the plurality of sub-pixels of the second pixel may be disposed on the other side (lower side in the drawing) in the column direction or the y-axis direction of the array of the sub-pixels of the first and second pixels, and another of the respective driving circuits for respectively driving the plurality of sub-pixels of the second pixel may be disposed on one side (upper side in the drawing) in the column direction or the y-axis direction of the array of the sub-pixels of the first and second pixels, and the other of the respective driving circuits for respectively driving the plurality of sub-pixels of the second pixel may be disposed on the other side (lower side in the drawing) in the column direction or the y-axis direction of the array of the sub-pixels of the first and second pixels.

Alternatively, a position of each of the driving circuits of the first to sixth sub-pixels 911, 912, 913, 914, 915, and 916 may be opposite to that in FIG. 9. The display panel 110 according to the present disclosure is not limited thereto.

According to an embodiment, the high potential voltage is applied to the first driving circuit 911a of the first sub-pixel R 911 via a first high potential voltage line EVDDL1 901 to operate the first sub-pixel R 911.

FIG. 9 illustrates that the first sub-pixel R 911 is disposed on the right side (in the x-axis direction or row direction) of the first high potential voltage line EVDDL1, and the first high potential voltage line EVDDL1 901 is connected to the first sub-pixel R 911. As such, the first high potential voltage line EVDDL1 901 may be disposed on one side (e.g., left side) in the x-axis direction of the first pixel including the sub-pixels 911, 912, and 913.

However, although not shown in FIG. 9, the sub-pixels G and B are also disposed on the left side in the x-axis direction of the first high potential voltage line EVDDL1 901, and the first high potential voltage line EVDDL1 901 is also connected to the sub-pixels G and B.

As such, the first high potential voltage line EVDDL1 901 is connected to the three sub-pixels R, G, and B.

According to an embodiment, the high potential voltage is applied to the fifth driving circuit 915a of the fifth sub-pixel G 915 and the sixth driving circuit 916a of the sixth sub-pixel B 916 via a second high potential voltage line EVDDL2 902 to operate the fifth sub-pixel G 915 and the sixth sub-pixel B 916.

FIG. 9 illustrates that the fifth sub-pixel G 915 and the sixth sub-pixel B 916 are disposed on the left side in the x-axis direction of the second high potential voltage line EVDDL2 902, and the second high potential voltage line EVDDL2 902 is connected to the fifth sub-pixel G 915 and the sixth sub-pixel B 916. As such, the second high potential voltage line EVDDL2 902 may be disposed on the other side (e.g., right side) in the x-axis direction of the second pixel including the sub-pixels 914, 915, and 916.

However, although not shown in FIG. 9, one sub-pixel R is also disposed on the right side (in the x-axis direction or row direction) of the second high potential voltage line EVDDL2 902, and the second high potential voltage line EVDDL2 902 is also connected to one sub-pixel R.

According to an embodiment, the high potential voltage is applied to the second driving circuit 912a of the second sub-pixel G 912, the third driving circuit 913a of the third sub-pixel B 913, and the fourth driving circuit 914a of the fourth sub-pixel R 914 via a third high potential voltage line EVDDL3 940 to operate the second sub-pixel G 912, the third sub-pixel B 913, and the fourth sub-pixel R 914. To this end, the third high potential voltage line EVDDL3 940 may be disposed between the first pixel including the sub-pixels 911, 912, and 913 and the second pixel including the sub-pixels 914, 915, and 916.

According to an embodiment, a first gate line 920 is disposed between the first sub-pixel 911 and the first driving circuit 911a, between the third sub-pixel 913 and the third driving circuit 913a, and between the fifth sub-pixel 915 and the fifth driving circuit 915a to supply the gate signal to the first sub-pixel 911, the third sub-pixel 913, and the fifth sub-pixel 915.

According to an embodiment, a second gate line 930 is disposed between the second sub-pixel 912 and the second driving circuit 912a, between the fourth sub-pixel 914 and the fourth driving circuit 914a, and between the sixth sub-pixel 916 and the sixth driving circuit 916a to supply the gate signal to the second sub-pixel 912, the fourth sub-pixel 914, and the sixth sub-pixel 916.

According to an embodiment, the first reference voltage line RVL1 is disposed between the second sub-pixel 912 and the third sub-pixel 913, and the second reference voltage line RVL2 is disposed between the fifth sub-pixel 915 and the sixth sub-pixel 916.

As described above, according to the third embodiment of the present disclosure, in the SRD (single rate driving) driving scheme based on three sub-pixels, the third high potential voltage line EVDD3 940 is disposed between the adjacent pixels so that the driving circuits of the first and second pixels are arranged so as to be asymmetrical with each other around the third high potential voltage line EVDD3 940, thereby suppressing the column line defect occurring between the odd-numbered row and the even-numbered row during the process due to the left-right asymmetry.

In one embodiment, a display panel comprises: a first pixel including a plurality of first sub-pixels; a second pixel including a plurality of second sub-pixels, the second pixel adjacent to the first pixel in a first direction; a first high potential voltage line on a first side of the first pixel in the first direction; a second high potential voltage line on a second side of the second pixel in the first direction; and a third high potential voltage line between the first pixel and the second pixel such that the third high potential voltage line is on a second side of the first pixel and a first side of the second pixel.

In one embodiment, the display panel further comprises: a plurality of driving circuits configured to drive the plurality of first sub-pixels of the first pixel and the plurality of second sub-pixels of the second pixel, and wherein at least one driving circuit from the plurality of driving circuits is on a first side of one of the plurality of first sub-pixels of the first pixel in a second direction that is different from the first direction and at least one driving circuit from the plurality of driving circuits is on a second side of another one of the plurality of first sub-pixels of the first pixel that is opposite the first side in the second direction, and at least one driving circuit from the plurality of driving circuits is on a first side of one of the plurality of second sub-pixels of the second pixel in the second direction and at least one driving circuit from the plurality of driving circuits is on a second side of another one of the plurality of second sub-pixels that is opposite the first side in the second direction.

In one embodiment, the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction, wherein the display panel further comprises a first driving circuit that is configured to drive the first sub-pixel, a second driving circuit that is configured to drive the second sub-pixel, and a third driving circuit that is configured to drive the third sub-pixel, wherein the first driving circuit is disposed on the first side of the first sub-pixel in the second direction, the second driving circuit is disposed on the first side of the second sub-pixel in the second direction, and the third driving circuit is disposed on the second side the third sub-pixel in the second direction.

In one embodiment, the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction, wherein the display panel further comprises a fourth driving circuit that is configured to drive the fourth sub-pixel, a fifth driving circuit that is configured to drive the fifth sub-pixel, and a sixth driving circuit that is configured to drive the sixth sub-pixel, wherein the fourth driving circuit is disposed on the second side of the fourth sub-pixel in the second direction, the fifth driving circuit is disposed on the second side of the fifth sub-pixel in the second direction, and the sixth driving circuit is disposed on the first side of the sixth sub-pixel in the second direction.

In one embodiment, the display panel further comprises: a plurality of gate lines that supply a gate signal to the first pixel and the second pixel, the plurality of gate lines including a first gate line between the first sub-pixel and the first driving circuit, between the second sub-pixel and the second driving circuit, and between the sixth sub-pixel and the sixth driving circuit.

In one embodiment, the plurality of gate lines include a second gate line between the third sub-pixel and the third driving circuit, between the fourth sub-pixel and the fourth driving circuit, and between the fifth sub-pixel and the fifth driving circuit.

In one embodiment, the first gate line supplies the gate signal to the first sub-pixel via the first driving circuit, the first gate line supplies the gate signal to the second sub-pixel via the second driving circuit, and the first gate line supplies the gate signal to the sixth sub-pixel via the sixth driving circuit.

In one embodiment, the second gate line supplies the gate signal to the third sub-pixel via the third driving circuit, the second gate line supplies the gate signal to the fourth sub-pixel via the fourth driving circuit, and the second gate line supplies the gate signal to the fifth sub-pixel via the fifth driving circuit.

In one embodiment, the third high potential voltage line is between the third sub-pixel of the first pixel and the fourth sub-pixel of the second pixel.

In one embodiment, the first high potential voltage line applies a first high potential voltage to the first driving circuit and the second driving circuit, the second high potential voltage line applies a second high potential voltage to the sixth driving circuit, and the third high potential voltage line applies a third high potential voltage to the third driving circuit, the fourth driving circuit, and the fifth driving circuit.

In one embodiment, the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction, wherein the display panel further comprises a first driving circuit that is configured to drive the first sub-pixel, a second driving circuit that is configured to drive the second sub-pixel, and a third driving circuit that is configured to drive the third sub-pixel, wherein the first driving circuit is disposed on the first side of the first sub-pixel in the second direction, the second driving circuit is disposed on the second side of the second sub-pixel in the second direction, and the third driving circuit is disposed on the second side of the third sub-pixel in the second direction.

In one embodiment, the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction, wherein the display panel further comprises a fourth driving circuit that is configured to drive the fourth sub-pixel, a fifth driving circuit that is configured to drive the fifth sub-pixel, and a sixth driving circuit configured to drive the sixth driving circuit, wherein the fourth driving circuit is disposed on the second side of the fourth sub-pixel in the second direction, the fifth driving circuit is disposed on the first side of the fifth sub-pixel in the second direction, and the sixth driving circuit is disposed on the first side of the sixth sub-pixel in the second direction.

In one embodiment, the display panel further comprises: a plurality of gate lines that supply a gate signal to the first pixel and the second pixel, the plurality of gate lines including a first gate line between the first sub-pixel and the first driving circuit, between the fifth sub-pixel and the fifth driving circuit, and between the sixth sub-pixel and the sixth driving circuit.

In one embodiment, the plurality of gate lines include a second gate line between the second sub-pixel and the second driving circuit, between the third sub-pixel and the third driving circuit, and between the fourth sub-pixel and the fourth driving circuit.

In one embodiment, the first high potential voltage line applies a first high potential voltage to the first driving circuit, the second high potential voltage line applies a second high potential voltage to the fifth driving circuit and the sixth driving circuit, and the third high potential voltage line applies a third high potential voltage to the second driving circuit, the third driving circuit, and the fourth driving circuit.

In one embodiment, the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction, wherein the display panel further comprises a first driving circuit that is configured to drive the first sub-pixel, a second driving circuit that is configured to drive the second sub-pixel, and a third driving circuit configured to drive the third sub-pixel, wherein the first driving circuit is disposed on the first side of the first sub-pixel in the second direction, the second driving circuit is disposed on the second side of the second sub-pixel in the second direction, and the third driving circuit is disposed on the first side of the third sub-pixel in the second direction.

In one embodiment, the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction, wherein the display panel further comprises a fourth driving circuit that is configured to drive the fourth sub-pixel, a fifth driving circuit that is configured to drive the fifth sub-pixel, and a sixth driving circuit configured to drive the sixth sub-pixel, wherein the fourth driving circuit is disposed on second side of the fourth sub-pixel in the second direction, the fifth driving circuit is disposed on the first side of the fifth sub-pixel in the second direction, and the sixth driving circuit is disposed on the second side of the sixth sub-pixel in the second direction.

In one embodiment, the display panel further comprises: a plurality of gate lines that supply a gate signal to the first pixel and the second pixel, the plurality of gate lines including a first gate line disposed between disposed between the first sub-pixel and the first driving circuit, between the third sub-pixel and the third driving circuit, and between the fifth sub-pixel and the fifth driving circuit.

In one embodiment, the first high potential voltage line applies a first high potential voltage to the first driving circuit, the second high potential voltage line applies a second high potential voltage to the fifth driving circuit and the sixth driving circuit, and the third high potential voltage line applies a third high potential voltage to the second driving circuit, the third driving circuit, and the fourth driving circuit.

In one embodiment, a display panel comprises: a pixel row including a first pixel comprising a plurality of first sub-pixels and a second pixel comprising a plurality of second sub-pixels, the second pixel adjacent to the first pixel in the pixel row along a first direction; a first high potential voltage line on a first side of the first pixel in a plan view of the display panel, the first high potential voltage line connected to at least one of the plurality of first sub-pixels of the first pixel; a second high potential voltage line on a second side of the second pixel in the plan view of the display panel, the second high potential voltage line connected to at least one of the plurality of second sub-pixels of the second pixel; and a third high potential voltage line between the first pixel and the second pixel, the third high potential voltage line connected to at least another one of the plurality of first sub-pixels of the first pixel and at least another one of the plurality of second sub-pixels of the second pixel.

In one embodiment, the display panel further comprises: a first gate line that supplies a first gate signal to at least one of the plurality of first sub-pixels of the first pixel and at least one of the plurality of second sub-pixels of the second pixel; and a second gate line that supplies a second gate signal to at least another one of the plurality of first sub-pixels of the first pixel and at least another one of the plurality of second sub-pixels of the second pixel.

In one embodiment, the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction, wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction, wherein the display panel further comprises a first driving circuit that is configured to drive the first sub-pixel, a second driving circuit that is configured to drive the second sub-pixel, a third driving circuit that is configured to drive the third sub-pixel, a fourth driving circuit that is configured to drive the fourth sub-pixel, a fifth driving circuit that is configured to drive the fifth sub-pixel, and a sixth driving circuit that is configured to drive the sixth sub-pixel, wherein the first driving circuit is disposed on the first side of the first sub-pixel in the second direction, the second driving circuit is disposed on the first side of the second sub-pixel in the second direction, and the third driving circuit is disposed on the second side the third sub-pixel in the second direction, wherein the fourth driving circuit is disposed on the second side of the fourth sub-pixel in the second direction, the fifth driving circuit is disposed on the second side of the fifth sub-pixel in the second direction, and the sixth driving circuit is disposed on the first side of the sixth sub-pixel in the second direction.

In one embodiment, the first gate line is between the first sub-pixel and the first driving circuit, between the second sub-pixel and the second driving circuit, and between the sixth sub-pixel and the sixth driving circuit, and wherein the second gate line is between the third sub-pixel and the third driving circuit, between the fourth sub-pixel and the fourth driving circuit, and between the fifth sub-pixel and the fifth driving circuit.

In one embodiment, the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction, wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction, wherein the display panel further comprises a first driving circuit that is configured to drive the first sub-pixel, a second driving circuit that is configured to drive the second sub-pixel, a third driving circuit that is configured to drive the third sub-pixel, a fourth driving circuit that is configured to drive the fourth sub-pixel, a fifth driving circuit that is configured to drive the fifth sub-pixel, and a sixth driving circuit configured to drive the sixth driving circuit, wherein the first driving circuit is disposed the first side of the first sub-pixel in the second direction, the second driving circuit is disposed on the second side of the second sub-pixel in the second direction, and the third driving circuit is disposed on the second side of the third sub-pixel in the second direction, wherein the fourth driving circuit is disposed on the second side of the fourth sub-pixel in the second direction, the fifth driving circuit is disposed on the first side of the fifth sub-pixel in the second direction, and the sixth driving circuit is disposed on the first side of the sixth sub-pixel in the second direction.

In one embodiment, wherein the first gate line is between the first sub-pixel and the first driving circuit, between the fifth sub-pixel and the fifth driving circuit, and between the sixth sub-pixel and the sixth driving circuit, and wherein the second gate line is between the second sub-pixel and the second driving circuit, between the third sub-pixel and the third driving circuit, and between the fourth sub-pixel and the fourth driving circuit.

In one embodiment, the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction, wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction, wherein the display panel further comprises a first driving circuit that is configured to drive the first sub-pixel, a second driving circuit that is configured to drive the second sub-pixel, a third driving circuit configured to drive the third sub-pixel, a fourth driving circuit that is configured to drive the fourth sub-pixel, a fifth driving circuit that is configured to drive the fifth sub-pixel, and a sixth driving circuit configured to drive the sixth sub-pixel, wherein the first driving circuit is disposed on the first side of the first sub-pixel in the second direction, the second driving circuit is disposed on the second side of the second sub-pixel in the second direction, and the third driving circuit is disposed on the first side of the third sub-pixel in the second direction, wherein the fourth driving circuit is disposed on second side of the fourth sub-pixel in the second direction, the fifth driving circuit is disposed on the first side of the fifth sub-pixel in the second direction, and the sixth driving circuit is disposed on the second side of the sixth sub-pixel in the second direction.

In one embodiment, the first gate line is disposed between the first sub-pixel and the first driving circuit, between the third sub-pixel and the third driving circuit, and between the fifth sub-pixel and the fifth driving circuit, and wherein the second gate line is disposed between the second sub-pixel and the second driving circuit, between the fourth sub-pixel and the fourth driving circuit, and between the sixth sub-pixel and the sixth driving circuit.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display panel comprising:
a first pixel including a plurality of first sub-pixels;
a second pixel including a plurality of second sub-pixels, the second pixel adjacent to the first pixel in a first direction;
a first high potential voltage line on a first side of the first pixel in the first direction;
a second high potential voltage line on a second side of the second pixel in the first direction; and
a third high potential voltage line between the first pixel and the second pixel such that the third high potential voltage line is on a second side of the first pixel and a first side of the second pixel.

2. The display panel of claim 1, wherein the display panel further comprises:
a plurality of driving circuits configured to drive the plurality of first sub-pixels of the first pixel and the plurality of second sub-pixels of the second pixel, and
wherein at least one driving circuit from the plurality of driving circuits is on a first side of one of the plurality of first sub-pixels of the first pixel in a second direction that is different from the first direction and at least one driving circuit from the plurality of driving circuits is on a second side of another one of the plurality of first sub-pixels of the first pixel that is opposite the first side in the second direction, and at least one driving circuit from the plurality of driving circuits is on a first side of one of the plurality of second sub-pixels of the second pixel in the second direction and at least one driving circuit from the plurality of driving circuits is on a second side of another one of the plurality of second sub-pixels that is opposite the first side in the second direction.

3. The display panel of claim 1, wherein the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction,
wherein the display panel further comprises a first driving circuit that is configured to drive the first sub-pixel, a second driving circuit that is configured to drive the second sub-pixel, and a third driving circuit that is configured to drive the third sub-pixel,
wherein the first driving circuit is disposed on the first side of the first sub-pixel in the second direction, the second driving circuit is disposed on the first side of the second sub-pixel in the second direction, and the third driving circuit is disposed on the second side the third sub-pixel in the second direction.

4. The display panel of claim 3, wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction,
wherein the display panel further comprises a fourth driving circuit that is configured to drive the fourth sub-pixel, a fifth driving circuit that is configured to drive the fifth sub-pixel, and a sixth driving circuit that is configured to drive the sixth sub-pixel,
wherein the fourth driving circuit is disposed on the second side of the fourth sub-pixel in the second direction, the fifth driving circuit is disposed on the second side of the fifth sub-pixel in the second direction, and the sixth driving circuit is disposed on the first side of the sixth sub-pixel in the second direction.

5. The display panel of claim 4, wherein the display panel further comprises:
a plurality of gate lines that supply a gate signal to the first pixel and the second pixel, the plurality of gate lines including a first gate line between the first sub-pixel and the first driving circuit, between the second sub-pixel and the second driving circuit, and between the sixth sub-pixel and the sixth driving circuit.

6. The display panel of claim 5, wherein the plurality of gate lines include a second gate line between the third sub-pixel and the third driving circuit, between the fourth sub-pixel and the fourth driving circuit, and between the fifth sub-pixel and the fifth driving circuit.

7. The display panel of claim 5, wherein the first gate line supplies the gate signal to the first sub-pixel via the first driving circuit, the first gate line supplies the gate signal to the second sub-pixel via the second driving circuit, and the first gate line supplies the gate signal to the sixth sub-pixel via the sixth driving circuit.

8. The display panel of claim 6, wherein the second gate line supplies the gate signal to the third sub-pixel via the third driving circuit, the second gate line supplies the gate signal to the fourth sub-pixel via the fourth driving circuit, and the second gate line supplies the gate signal to the fifth sub-pixel via the fifth driving circuit.

9. The display panel of claim 4, wherein the third high potential voltage line is between the third sub-pixel of the first pixel and the fourth sub-pixel of the second pixel.

10. The display panel of claim 7, wherein the first high potential voltage line applies a first high potential voltage to the first driving circuit and the second driving circuit, the second high potential voltage line applies a second high potential voltage to the sixth driving circuit, and the third high potential voltage line applies a third high potential voltage to the third driving circuit, the fourth driving circuit, and the fifth driving circuit.

11. The display panel of claim 1, wherein the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction,
wherein the display panel further comprises a first driving circuit that is configured to drive the first sub-pixel, a second driving circuit that is configured to drive the second sub-pixel, and a third driving circuit that is configured to drive the third sub-pixel,
wherein the first driving circuit is disposed on the first side of the first sub-pixel in the second direction, the second driving circuit is disposed on the second side of the second sub-pixel in the second direction, and the third driving circuit is disposed on the second side of the third sub-pixel in the second direction.

12. The display panel of claim 11, wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction,
wherein the display panel further comprises a fourth driving circuit that is configured to drive the fourth sub-pixel, a fifth driving circuit that is configured to drive the fifth sub-pixel, and a sixth driving circuit configured to drive the sixth driving circuit,
wherein the fourth driving circuit is disposed on the second side of the fourth sub-pixel in the second direction, the fifth driving circuit is disposed on the first side of the fifth sub-pixel in the second direction, and the sixth driving circuit is disposed on the first side of the sixth sub-pixel in the second direction.

13. The display panel of claim 12, wherein the display panel further comprises:
a plurality of gate lines that supply a gate signal to the first pixel and the second pixel, the plurality of gate lines including a first gate line between the first sub-pixel and the first driving circuit, between the fifth sub-pixel and the fifth driving circuit, and between the sixth sub-pixel and the sixth driving circuit.

14. The display panel of claim 13, wherein the plurality of gate lines include a second gate line between the second sub-pixel and the second driving circuit, between the third sub-pixel and the third driving circuit, and between the fourth sub-pixel and the fourth driving circuit.

15. The display panel of claim 12, wherein the first high potential voltage line applies a first high potential voltage to the first driving circuit, the second high potential voltage line applies a second high potential voltage to the fifth driving circuit and the sixth driving circuit, and the third high potential voltage line applies a third high potential voltage to the second driving circuit, the third driving circuit, and the fourth driving circuit.

16. The display panel of claim 1, wherein the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction,
wherein the display panel further comprises a first driving circuit that is configured to drive the first sub-pixel, a second driving circuit that is configured to drive the second sub-pixel, and a third driving circuit configured to drive the third sub-pixel,
wherein the first driving circuit is disposed on the first side of the first sub-pixel in the second direction, the second driving circuit is disposed on the second side of the second sub-pixel in the second direction, and the third driving circuit is disposed on the first side of the third sub-pixel in the second direction.

17. The display panel of claim 16, wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction,
wherein the display panel further comprises a fourth driving circuit that is configured to drive the fourth sub-pixel, a fifth driving circuit that is configured to drive the fifth sub-pixel, and a sixth driving circuit configured to drive the sixth sub-pixel,
wherein the fourth driving circuit is disposed on second side of the fourth sub-pixel in the second direction, the fifth driving circuit is disposed on the first side of the fifth sub-pixel in the second direction, and the sixth driving circuit is disposed on the second side of the sixth sub-pixel in the second direction.

18. The display panel of claim 17, wherein the display panel further comprises:
a plurality of gate lines that supply a gate signal to the first pixel and the second pixel, the plurality of gate lines including a first gate line disposed between disposed between the first sub-pixel and the first driving circuit, between the third sub-pixel and the third driving circuit, and between the fifth sub-pixel and the fifth driving circuit.

19. The display panel of claim 17, wherein the first high potential voltage line applies a first high potential voltage to the first driving circuit, the second high potential voltage line applies a second high potential voltage to the fifth driving circuit and the sixth driving circuit, and the third high potential voltage line applies a third high potential voltage to the second driving circuit, the third driving circuit, and the fourth driving circuit.

20. A display device comprising:
the display panel of claim 1;
a data driver configured to supply a data voltage to the display panel via a plurality of data lines; and
a gate driver configured to supply a gate signal to the display panel via a plurality of gate lines.

21. A display panel comprising:
a pixel row including a first pixel comprising a plurality of first sub-pixels and a second pixel comprising a plurality of second sub-pixels, the second pixel adjacent to the first pixel in the pixel row along a first direction;
a first high potential voltage line on a first side of the first pixel in a plan view of the display panel, the first high potential voltage line connected to at least one of the plurality of first sub-pixels of the first pixel;
a second high potential voltage line on a second side of the second pixel in the plan view of the display panel, the second high potential voltage line connected to at least one of the plurality of second sub-pixels of the second pixel; and
a third high potential voltage line between the first pixel and the second pixel, the third high potential voltage line connected to at least another one of the plurality of first sub-pixels of the first pixel and at least another one of the plurality of second sub-pixels of the second pixel.

22. The display panel of claim 21, further comprising:
a first gate line that supplies a first gate signal to at least one of the plurality of first sub-pixels of the first pixel and at least one of the plurality of second sub-pixels of the second pixel; and
a second gate line that supplies a second gate signal to at least another one of the plurality of first sub-pixels of the first pixel and at least another one of the plurality of second sub-pixels of the second pixel.

23. The display panel of claim 22, wherein the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction,
wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction,
wherein the display panel further comprises a first driving circuit that is configured to drive the first sub-pixel, a second driving circuit that is configured to drive the second sub-pixel, a third driving circuit that is configured to drive the third sub-pixel, a fourth driving circuit that is configured to drive the fourth sub-pixel, a fifth driving circuit that is configured to drive the fifth sub-pixel, and a sixth driving circuit that is configured to drive the sixth sub-pixel,
wherein the first driving circuit is disposed on the first side of the first sub-pixel in the second direction, the second driving circuit is disposed on the first side of the second sub-pixel in the second direction, and the third driving circuit is disposed on the second side the third sub-pixel in the second direction,
wherein the fourth driving circuit is disposed on the second side of the fourth sub-pixel in the second direction, the fifth driving circuit is disposed on the second side of the fifth sub-pixel in the second direction, and the sixth driving circuit is disposed on the first side of the sixth sub-pixel in the second direction.

24. The display panel of claim 23, wherein the first gate line is between the first sub-pixel and the first driving circuit, between the second sub-pixel and the second driving circuit, and between the sixth sub-pixel and the sixth driving circuit, and
wherein the second gate line is between the third sub-pixel and the third driving circuit, between the fourth sub-pixel and the fourth driving circuit, and between the fifth sub-pixel and the fifth driving circuit.

25. The display panel of claim 22, wherein the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction,
wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction,
wherein the display panel further comprises a first driving circuit that is configured to drive the first sub-pixel, a second driving circuit that is configured to drive the second sub-pixel, a third driving circuit that is configured to drive the third sub-pixel, a fourth driving circuit that is configured to drive the fourth sub-pixel, a fifth driving circuit that is configured to drive the fifth sub-pixel, and a sixth driving circuit configured to drive the sixth driving circuit,
wherein the first driving circuit is disposed the first side of the first sub-pixel in the second direction, the second driving circuit is disposed on the second side of the second sub-pixel in the second direction, and the third driving circuit is disposed on the second side of the third sub-pixel in the second direction,
wherein the fourth driving circuit is disposed on the second side of the fourth sub-pixel in the second direction, the fifth driving circuit is disposed on the first side of the fifth sub-pixel in the second direction, and the sixth driving circuit is disposed on the first side of the sixth sub-pixel in the second direction.

26. The display panel of claim 25, wherein the first gate line is between the first sub-pixel and the first driving circuit, between the fifth sub-pixel and the fifth driving circuit, and between the sixth sub-pixel and the sixth driving circuit, and
wherein the second gate line is between the second sub-pixel and the second driving circuit, between the third sub-pixel and the third driving circuit, and between the fourth sub-pixel and the fourth driving circuit.

27. The display panel of claim 22, the first pixel includes a first sub-pixel having a first side and a second side that is opposite the first side in a second direction that is different from the first direction, a second sub-pixel having a first side and a second side that is opposite the first side in the second direction, and a third sub-pixel having a first side and a second side that is opposite the first side in the second direction, and the first sub-pixel, the second sub-pixel, and the third sub-pixel are sequentially arranged in the first direction,
wherein the second pixel includes a fourth sub-pixel having a first side and a second side that is opposite the first side in the second direction, a fifth sub-pixel having a first side and a second side that is opposite the first side in the second direction, and a sixth sub-pixel having a first side and a second side that is opposite the first side in the second direction, and the fourth sub-pixel, the fifth sub-pixel, and the sixth sub-pixel are sequentially arranged in the first direction,
wherein the display panel further comprises a first driving circuit that is configured to drive the first sub-pixel, a second driving circuit that is configured to drive the second sub-pixel, a third driving circuit configured to drive the third sub-pixel, a fourth driving circuit that is configured to drive the fourth sub-pixel, a fifth driving circuit that is configured to drive the fifth sub-pixel, and a sixth driving circuit configured to drive the sixth sub-pixel,
wherein the first driving circuit is disposed on the first side of the first sub-pixel in the second direction, the second driving circuit is disposed on the second side of the second sub-pixel in the second direction, and the third driving circuit is disposed on the first side of the third sub-pixel in the second direction,
wherein the fourth driving circuit is disposed on second side of the fourth sub-pixel in the second direction, the fifth driving circuit is disposed on the first side of the fifth sub-pixel in the second direction, and the sixth driving circuit is disposed on the second side of the sixth sub-pixel in the second direction.

28. The display panel of claim 27, wherein the first gate line is disposed between the first sub-pixel and the first driving circuit, between the third sub-pixel and the third driving circuit, and between the fifth sub-pixel and the fifth driving circuit, and
wherein the second gate line is disposed between the second sub-pixel and the second driving circuit, between the fourth sub-pixel and the fourth driving circuit, and between the sixth sub-pixel and the sixth driving circuit.
